(19) United States
(12) Patent Application Publication
(10) Pub. No.: US 2026/0163586 A1
(43) Pub. Date: Jun. 11, 2026

(54) AD CONVERSION CIRCUIT, PHOTOELECTRIC CONVERSION DEVICE, IMAGE CAPTURE DEVICE, AND MOBILE OBJECT

(71) Applicant: CANON KABUSHIKI KAISHA, Tokyo (JP)

(72) Inventor: MASANORI FURUTA, Kanagawa (JP)

(21) Appl. No.: 19/360,026

(22) Filed: Oct. 16, 2025

Related U.S. Application Data
(63) Continuation of application No. PCT/JP2024/014820, filed on Apr. 12, 2024.

(30) Foreign Application Priority Data
Apr. 17, 2023 (JP) 2023-067376
Sep. 25, 2023 (JP) 2023-161706
Jan. 25, 2024 (JP) 2024-009601

(51) Int. Cl. H03M 3/00; H04N 25/78; H04N 25/79

(52) U.S. Cl. CPC H03M 3/458; H03M 3/354; H04N 25/78; H04N 25/79

(57) ABSTRACT

An AD conversion circuit for converting an analog signal provided to an input terminal into a digital signal, includes a continuous-time delta-sigma AD converter including an integration circuit configured to integrate a differential signal; and a switching circuit configured to, during a first period, provide the analog signal provided to the input terminal to the continuous-time delta-sigma AD converter, and during a second period after the first period, provide a voltage signal that corresponds to the voltage output from the integration circuit at the end of the first period to the continuous-time delta-sigma AD converter.

### CROSS-REFERENCE TO RELATED APPLICATIONS

This application is a Continuation of International Patent Application No. PCT/JP2024/014820, filed Apr. 12, 2024, which claims the benefit of Japanese Patent Application No. 2023-067376 filed on Apr. 17, 2023, Japanese Patent Application No. 2023-161706 filed on Sep. 25, 2023, and Japanese Patent Application No. 2024-009601 filed on Jan. 25, 2024, all of which are hereby incorporated by reference herein in their entirety.

### BACKGROUND

### Field of the Technology

The present invention relates to an AD conversion circuit, a photoelectric conversion device, an image capture device, and a mobile object.

### Description of the Related Art

Analog-to-digital converters (ADCs) are known that convert analog signals of pixel outputs in solid-state image capture devices into digital signals. PTL 1 discloses a discrete-time delta-sigma ADC constituted by a switched-capacitor integration circuit and a comparator. PTL 2 discloses a two-stage ADC constituted by a discrete-time delta-sigma ADC and a slope-type ADC as a circuit technology for increasing the AD conversion speed of a discrete-time delta-sigma ADC. In this two-stage ADC, the delta-sigma ADC performs AD conversion corresponding to an upper bit string, and the residual voltage of the ADC corresponding to the upper bit string is used as input to the slope-type ADC, which then performs AD conversion corresponding to a lower bit string. While a discrete-time delta-sigma ADC achieves a faster AD conversion speed, it also requires frequent charging of capacitors, which are constituent elements of the ADC, using analog pixel output signals, which can increase the power consumption of the pixel output drive circuit. PTL 3 discloses a second-order continuous-time delta-sigma ADC as a technique for reducing the power consumption of a pixel output drive circuit. This second-order continuous time delta-sigma ADC includes a voltage-current conversion circuit, an integration circuit constituted by a capacitor and a current-steering digital-to-analog conversion circuit, and a comparator. NPL 1 discloses a two-stage continuous time delta-sigma ADC as a technique for increasing the speed of a second-order continuous time delta-sigma ADC. In this two-stage continuous-time delta-sigma ADC, an ADC that performs AD conversion corresponding to the upper bit string and an ADC that performs AD conversion corresponding to the lower bit string using the residual voltage of the ADC corresponding to the upper bits as input are cascaded.

The two-stage continuous-time delta-sigma ADC is useful as a technology that realizes high-speed A/D conversion while reducing a pixel output drive load. On the other hand, because an ADC that performs A/D conversion corresponding to an upper bit string and an ADC that performs A/D conversion corresponding to a lower bit string are required, the large circuit mounting area is an issue.

### CITATION LIST

### Patent Literature

PTL 1: U.S. Patent Application Publication No. 2013/0162857
PTL 2: U.S. Patent Application Publication No. 2009/0261998
PTL 3: International Publication No. 2018/163679

### Non-Patent Literature

NPL 1: “A Power-Efficient Continuous-Time Incremental Sigma-Delta ADC for Neural Recording Systems,” IEEE Transactions on Circuits and Systems I: Regular Papers (Volume: 62, Issue: 6, June 2015)
NPL 2: “A Micro-Power Two-Step Incremental Analog-to-Digital Converter,” IEEE Journal of Solid-State Circuits (Volume: 50, Issue: 8, August 2015)

### SUMMARY

The present disclosure includes a technique that is advantageous for reducing the circuit scale of a continuous-time delta-sigma AD conversion circuit.

One aspect of the present disclosure relates to an AD conversion circuit for converting an analog signal provided to an input terminal into a digital signal, the AD conversion circuit including: a continuous-time delta-sigma AD converter including an integration circuit that integrates a differential signal; and a switching circuit that, during a first period, provides the analog signal provided to the input terminal to the continuous-time delta-sigma AD converter, and during a second period after the first period, provides a voltage signal corresponding to the voltage output from the integration circuit at the end of the first period to the continuous-time delta-sigma AD converter.

### BRIEF DESCRIPTION OF DRAWINGS

FIG. 1 is a diagram showing a configuration of a two-stage continuous-time delta-sigma AD conversion circuit according to a first embodiment.

FIG. 2 is an operation timing diagram of the two-stage continuous-time delta-sigma AD conversion circuit according to the first embodiment.

FIG. 3 is a diagram showing a first configuration example of a continuous-time delta-sigma converter in the two-stage continuous-time delta-sigma conversion circuit according to the first embodiment.

FIG. 4 is a diagram showing a second configuration example of the continuous-time delta-sigma converter in the two-stage continuous-time delta-sigma conversion circuit according to the first embodiment.

FIG. 5 is a diagram showing another configuration example of an integrator according to the first embodiment.

FIG. 6 is a diagram showing a configuration example of a comparison circuit in the two-stage continuous-time delta-sigma conversion circuit according to the first embodiment.

FIG. 7A is a diagram showing a configuration example of a residual voltage holding circuit in the two-stage continuous-time delta-sigma conversion circuit according to the first embodiment.

FIG. 7B is a diagram showing an example of the operation of the residual voltage holding circuit in the two-stage continuous-time delta-sigma conversion circuit according to the first embodiment.

FIG. 8 is a diagram showing a configuration of a two-stage continuous-time delta-sigma AD conversion circuit according to a second embodiment.

FIG. 9 is a diagram showing a first configuration example of a continuous-time delta-sigma converter in the two-stage continuous-time delta-sigma conversion circuit according to the second embodiment.

FIG. 10 is a diagram showing a second configuration example of the continuous-time delta-sigma converter in the two-stage continuous-time delta-sigma conversion circuit according to the second embodiment.

FIG. 11 is a diagram showing a third configuration example of the continuous-time delta-sigma converter in the two-stage continuous-time delta-sigma conversion circuit according to the second embodiment.

FIG. 12 is a diagram showing the operation of the third configuration example shown in FIG. 11.

FIG. 13 is a diagram showing a configuration of a two-stage continuous-time delta-sigma AD conversion circuit according to a third embodiment.

FIG. 14 is a diagram showing the configuration of the two-stage continuous-time delta-sigma AD conversion circuit according to the third embodiment.

FIG. 15 is a diagram showing a configuration of a photoelectric conversion device according to a seventh embodiment.

FIG. 16 is a diagram showing an example of a configuration of a photoelectric conversion system according to an embodiment.

FIG. 17A is a diagram showing a configuration of a photoelectric conversion system or a mobile object according to another embodiment.

FIG. 17B is a diagram showing the configuration of the photoelectric conversion system or the mobile object according to the other embodiment.

FIG. 18 is a diagram showing a configuration of an analog circuit unit in a two-stage continuous-time delta-sigma conversion circuit according to a fourth embodiment.

FIG. 19 is a diagram showing a configuration example of the analog circuit unit in the two-stage continuous-time delta-sigma conversion circuit according to the fourth embodiment.

FIG. 20A is a diagram showing a first configuration example of a switching circuit and a buffer circuit in the two-stage continuous-time delta-sigma conversion circuit according to the fourth embodiment.

FIG. 20B is a diagram showing operation of the first configuration example of the switching circuit and the buffer circuit in the two-stage continuous-time delta-sigma conversion circuit according to the fourth embodiment.

FIG. 21A is a diagram showing a second configuration example of the switching circuit and the buffer circuit in the two-stage continuous-time delta-sigma conversion circuit according to the fourth embodiment.

FIG. 21B is a diagram showing operation of the second configuration example of the switching circuit and the buffer circuit in the two-stage continuous-time delta-sigma conversion circuit according to the fourth embodiment.

FIG. 21C is a diagram showing the operation of the second configuration example of the switching circuit and the buffer circuit in the two-stage continuous-time delta-sigma conversion circuit according to the fourth embodiment.

FIG. 22 is a diagram showing a configuration example of an analog circuit unit in a two-stage continuous-time delta-sigma conversion circuit according to a fifth embodiment.

FIG. 23A is a diagram showing a configuration example of a switching circuit and a buffer circuit in the two-stage continuous-time delta-sigma conversion circuit according to the fifth embodiment.

FIG. 23B is a diagram showing operation of a second configuration example of the switching circuit and the buffer circuit in the two-stage continuous-time delta-sigma conversion circuit according to the fifth embodiment.

FIG. 23C is a diagram showing operation of the switching circuit and the buffer circuit in the two-stage continuous-time delta-sigma conversion circuit according to the fifth embodiment.

FIG. 24 is a diagram showing a configuration of a two-stage continuous-time delta-sigma AD conversion circuit according to a sixth embodiment.

FIG. 25 is a diagram showing a first configuration example of the continuous-time delta-sigma converter in a two-stage continuous-time delta-sigma conversion circuit according to the sixth embodiment.

FIG. 26 is a diagram showing a second configuration example of the continuous-time delta-sigma converter in the two-stage continuous-time delta-sigma conversion circuit according to the sixth embodiment.

FIG. 27 is a diagram showing a configuration example of an internal voltage adjustment circuit.

### DESCRIPTION OF EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

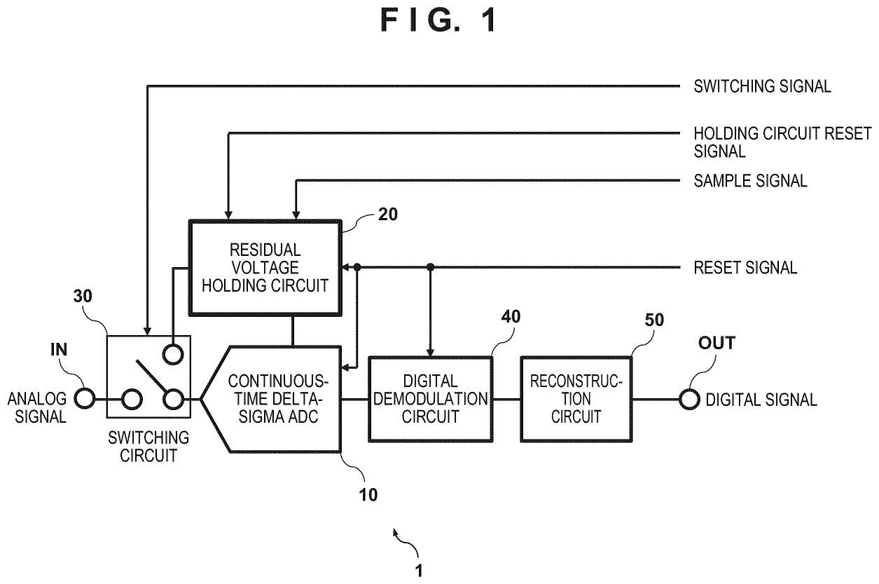

FIG. 1 shows a configuration of an AD conversion circuit 1 according to a first embodiment of the present disclosure. The AD conversion circuit 1 is configured as a two-stage continuous time delta-sigma AD conversion circuit. The AD conversion circuit 1 converts an analog signal provided to an input terminal IN into a digital signal and outputs the result from an output terminal OUT. The AD conversion circuit 1 may include a continuous-time delta-sigma AD converter 10 and a switching circuit 30. The AD conversion circuit 1 may also include a residual voltage holding circuit 20, a digital demodulation circuit 40, and a reconstruction circuit 50. The continuous-time delta-sigma AD converter 10 may include an integration circuit that integrates a differential signal. During a first period, the switching circuit 30 provides the analog signal provided to the input terminal IN to the continuous-time delta-sigma AD converter 10. In addition, during a second period after the first period, the switching circuit 30 provides a voltage signal corresponding to the voltage output from the integration circuit of the continuous-time delta-sigma AD converter 10 at the end of the first period to the continuous-time delta-sigma AD converter 10. The first period is a period during which AD conversion is performed to generate an upper bit string of a digital signal corresponding to an analog signal provided to the input terminal IN. The second period is a period during which AD conversion is performed to generate a lower bit string of a digital signal corresponding to the analog signal provided to the input terminal IN. The upper bit string can be constituted by a plurality of bits. In addition, the lower bit string can be constituted by a plurality of bits.

The residual voltage holding circuit 20 holds (samples) a voltage signal corresponding to the residual voltage output from the continuous-time delta-sigma AD converter 10 at the end of the first period, and supplies the voltage signal to the switching circuit 30 in the second period. The residual voltage holding circuit 20 can be controlled by, for example, a holding circuit reset signal and a sample signal.

In the first period, the continuous-time delta-sigma AD converter 10 performs A/D conversion corresponding to the upper bit string, and at the end of the first period, a voltage signal corresponding to the residual voltage held by the residual voltage holding circuit 20 is provided to the continuous-time delta-sigma AD converter 10 by the switching circuit 30. Thereafter, in the second period, the continuous-time delta-sigma AD converter 10 performs A/D conversion corresponding to the lower bit string. In the first period, a time-series delta-sigma modulated signal (upper bit string) output from the continuous-time delta-sigma AD converter 10 is demodulated by the digital demodulation circuit 40 into a multi-bit digital signal. In addition, in the second period, the time-series delta-sigma modulated signal (lower bit string) output from the continuous-time delta-sigma AD converter 10 is demodulated by the digital demodulation circuit 40 into a multi-bit digital signal. The reconstruction circuit 50 generates an output digital signal based on the digital signal of the upper bit string and the digital signal of the lower bit string demodulated by the digital demodulation circuit 40. The internal signals of the continuous-time delta-sigma AD converter 10 and the digital demodulation circuit 40 are reset in accordance with the reset signal before the start of the first period and before the start of the second period. With this configuration, by using one continuous-time delta-sigma AD converter 10 and one residual voltage holding circuit 20, it is possible to realize the AD conversion circuit 1 as a two-stage continuous-time delta-sigma AD conversion circuit.

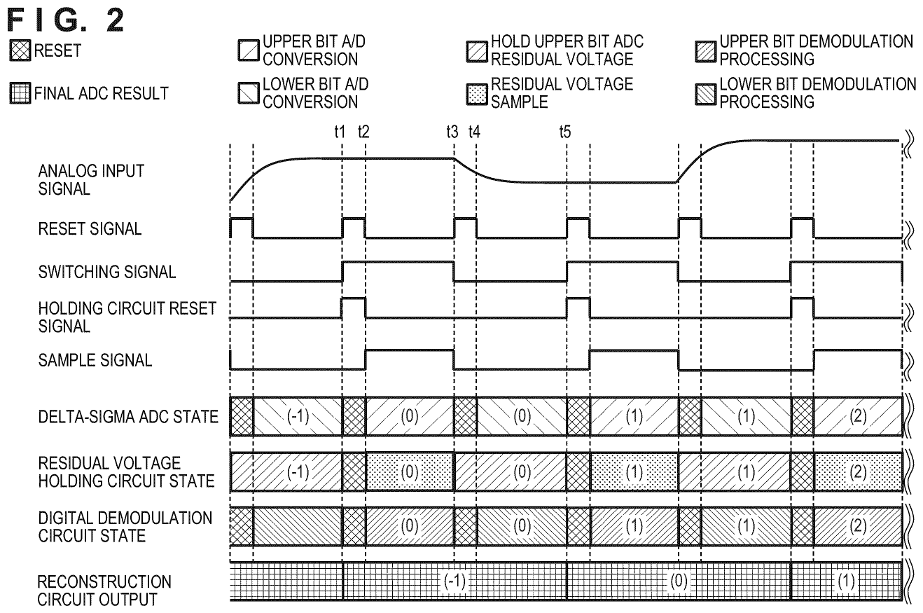

FIG. 2 shows an operation timing diagram of the AD conversion circuit 1 shown in FIG. 1. Here, as an example of the operation of the AD conversion circuit 1, processing in which the reconstruction circuit 50 outputs the final AD conversion result (final ADC result) (0) will be described. In the period from time t1 to time t2, the continuous-time delta-sigma AD converter 10 and the digital demodulation circuit 40 are reset with the reset signal in a high state. At the same time, the residual voltage holding circuit 20 is reset with the holding circuit reset signal in a high state. The period from time t2 to time t3 is the first period. At time t2, when the reset signal enters a low state, the continuous-time delta-sigma AD converter 10 starts A/D conversion corresponding to the upper bit string, and the residual voltage holding circuit 20 starts sampling the residual voltage (a voltage signal corresponding to the residual voltage). Also, at time t2, the digital demodulation circuit 40 starts demodulating the upper bit string. At time t3, the A/D conversion corresponding to the upper bit string is completed. At time t3, the residual voltage holding circuit 20 starts to hold the residual voltage (a voltage signal corresponding to the residual voltage), which is the output voltage of the continuous-time delta-sigma AD converter 10 at the end of the first period, and at the same time, the reconstruction circuit 50 acquires a multi-bit demodulated signal corresponding to the upper bit string.

Thereafter, in the period from time t3 to time t4, the reset signal enters the high state again, and the continuous-time delta-sigma AD converter 10 and the digital demodulation circuit 40 are reset. The second period is from time t4 to time t5. At time t4, when the reset signal enters the low state, the continuous-time delta-sigma AD converter 10 starts A/D conversion corresponding to the lower bit string, and the digital demodulation circuit 40 starts demodulation processing of the lower bit string. At time t5, the A/D conversion corresponding to the lower bit string is completed. In response to this, the reconstruction circuit 50 acquires a multi-bit demodulated signal corresponding to the lower bit string. Thereafter, due to the reconstruction circuit 50 acquiring the multi-bit demodulated signal corresponding to the lower bit string and performing reconstruction processing using the multi-bit demodulated signal corresponding to the above-described upper bit string, the final ADC result corresponding to the output digital signal is output.

The AD conversion circuit 1 performs the above A/D conversion repeatedly to perform A/D conversion on any input analog signal. Note that it is assumed that the input analog signal during the A/D conversion period corresponding to the upper bit string is constant.

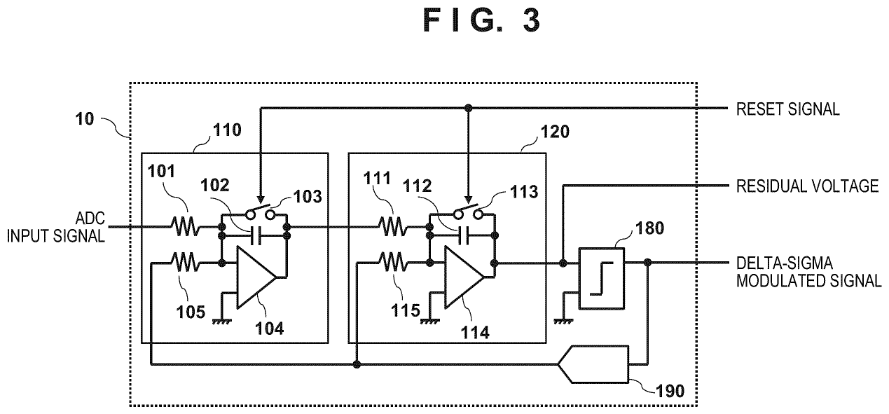

FIG. 3 shows a configuration of a second-order continuous-time delta-sigma AD converter as a first configuration example of the continuous-time delta-sigma AD converter 10. The continuous-time delta-sigma AD converter 10 of the first configuration example can include a first integrator 110, a second integrator 120, a comparator 180, and a digital-to-analog converter (DA converter) 190. The first integrator 110 can include, for example, resistors 101 and 105, a capacitor 102, a switch 103, and an amplifier 104. The second integrator 120 can include, for example, resistors 111 and 115, a capacitor 112, a switch 113, and an amplifier 114.

The input terminal of the first integrator 110 is supplied with the output of the switching circuit 30 as an ADC input signal. The output of the first integrator 110 is supplied to the second integrator 120, and the output of the second integrator 120 is supplied to the comparator 180. The output of the comparator 180 is supplied to the DA converter 190, and the output of the DA converter 190 is supplied to the resistor 105 in the first integrator 110 and the resistor 115 in the second integrator 120. The output of the second integrator 120 is output as the residual voltage of the continuous-time delta-sigma AD converter 10.

In the continuous-time delta-sigma AD converter 10, when the reset signal is in a high state, the capacitors 102 and 112 are reset. When the reset signal is in a low state, the first integrator 110 integrates the differential signal between the ADC input signal and the output of the DA converter 190. The second integrator 120 integrates the differential signal between the output voltage of the first integrator 110 and the output of the DA converter 190. The comparator 180 receives a differential signal between the output voltage of the second integrator 120 and a reference signal, and performs a comparison operation using a clock signal (not shown). The DA converter 190 outputs an analog voltage in response to the output signal of the comparator 180. The DA converter 190 can be configured to output an analog voltage corresponding to an input signal according to, for example, a 1-bit transfer function expressed by Equation (1).

$$\begin{matrix}[ Math . 1 ] & \\ DACout ( DACin ) = \{ \begin{matrix}Vr , & ( DACin = 1 ) \\ 0 , & ( DACin = 0 )\end{matrix} & ( 1 )\end{matrix}$$

Here, DACin is the output signal of the comparator 180, Vr is a reference signal (not shown) in the continuous-time delta-sigma AD converter 10, DACout is the output signal of the DA converter 190, and the reference signal is 0. The AD conversion circuit 1 in FIG. 3 repeatedly performs integration, comparison, and digital-to-analog conversion in the period up to when the reset signal changes from a low state to a high state.

In the example of FIG. 3, the AD conversion circuit 1 is configured as a second-order continuous-time delta-sigma AD conversion circuit. In the example of FIG. 3, the comparator 180 and the DA converter 190 of the AD conversion circuit 1 each have a 1-bit configuration. However, the comparator 180 and the DA converter 190 may be multi-bit, and the resistor 105 of the first integrator 110 and the resistor 115 of the second integrator 120 may be increased in number according to the resolution of the comparator 180 and the DA converter 190, and connected in parallel. By configuring the comparator 180 and the DA converter 190 with a plurality of bits, the AD conversion speed of the continuous-time delta-sigma AD converter 10 can be increased. In addition, a third-order or higher continuous-time delta-sigma AD converter may be configured by adding one or more integrators between the second integrator 120 and the comparator 180. The AD conversion speed of the continuous-time delta-sigma AD converter 10 can be increased by increasing the number of integrators.

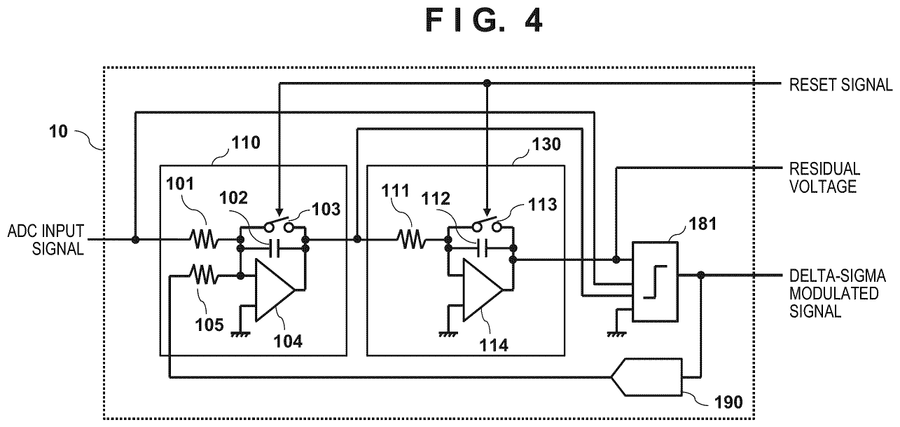

FIG. 4 shows a configuration of a second-order continuous-time delta-sigma AD converter having a feedforward path as a second configuration example of the continuous-time delta-sigma AD converter 10. The continuous-time delta-sigma AD converter 10 of the second configuration example can include a first integrator 110, a second integrator 130, a four-input comparator 181, and a digital-to-analog converter (DA converter) 190. The first integrator 110 can include, for example, resistors 101 and 105, a capacitor 102, a switch 103, and an amplifier 104. The second integrator 130 can include a resistor 111, a capacitor 112, a switch 113, and an amplifier 114.

The input terminal of the first integrator 110 is supplied with the output of the switching circuit 30 as an ADC input signal. The output of the first integrator 110 is supplied to the second integrator 130, and the output of the second integrator 130 is supplied to the four-input comparator 181. The output of the four-input comparator 181 is supplied to the DA converter 190, and the output of the DA converter 190 is supplied to the resistor 105 in the first integrator 110.

The operation of the second configuration example shown in FIG. 4 is similar to the operation of the first configuration example shown in FIG. 3. In the second configuration example, the signal supplied from the switching circuit 30 as the ADC input signal is supplied to the four-input comparator 181. The output of the first integrator 110 and the output of the second integrator 130 are also supplied to the four-input comparator 181. With this configuration, it is possible to suppress the amplitude of the signals output from the first integrator 110 and the second integrator 130, and the influence of the nonlinearity of the amplifiers 104 and 114 can be suppressed. This makes it possible to improve the nonlinear distortion characteristics of the continuous-time delta-sigma AD converter 10.

In the example of FIG. 4, the AD conversion circuit 1 is configured as a second-order continuous-time delta-sigma ADC. In the example of FIG. 4, the four-input comparator 181 and the DA converter 190 of the AD conversion circuit 1 each have a one-bit configuration. However, the four-input comparator 181 and the DA converter 190 may be multi-bit, and the resistor 105 of the first integrator 110 may be increased in number according to the resolution of the four-input comparator 181 and the DA converter 190, and connected in parallel. In addition, a third-order or higher continuous-time delta-sigma AD converter may be configured by adding one or more integrators between the second integrator 130 and the four-input comparator 181. The AD conversion speed of the continuous-time delta-sigma AD converter 10 can be increased by using a plurality of bits in the comparator and the DA converter and increasing the number of integrators.

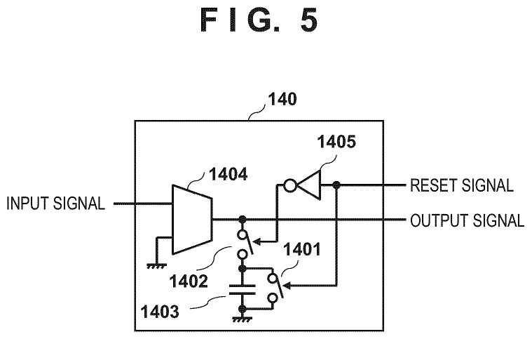

FIG. 5 shows the configuration of a gm-C integrator 140 serving as another configuration example of the integrator in the continuous-time delta-sigma AD converter 10. The integrator 140 may include switches 1401 and 1402, a capacitor 1403, a transconductance 1404, and an inverter 1405. The switch 1401 is controlled by a reset signal, and the switch 1402 is controlled by a reset signal inverted by the inverter 1405. When the reset signal is in a high state, the capacitor 1403 is reset. When the reset signal is in a low state, an integration operation is performed by the capacitor 1403 and the differential current between the current generated by the transconductance 1404 in response to the input signal and the output signal current of the DA converter 190. When the gm-C integrator 140 is used as the first integrator 110, the output of the DA converter 190 is connected to the output of the transconductance 1404. This configuration realizes the same function as an integrator constituted by a resistor, a capacitor, and an amplifier, while reducing power consumption.

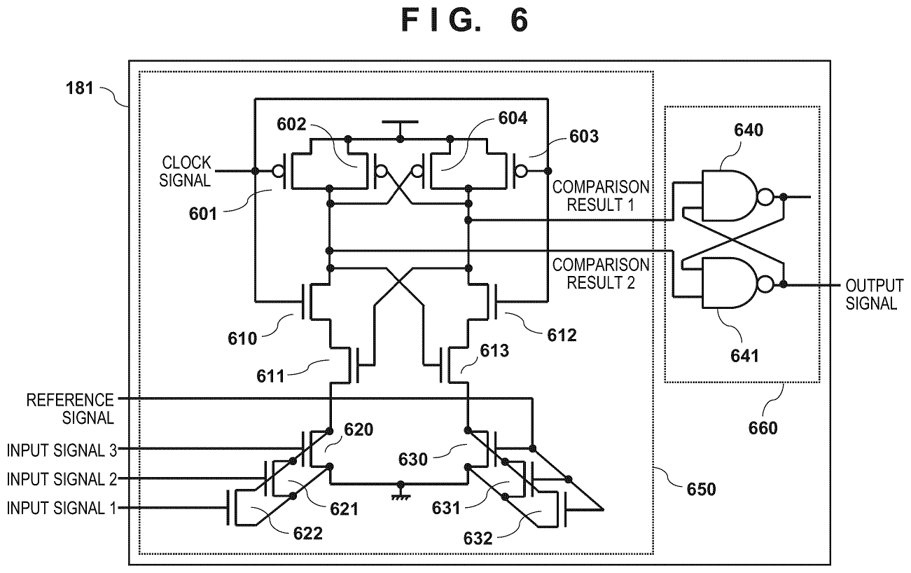

FIG. 6 shows an example of a configuration of the four-input comparator 181. The four-input comparator 181 may include a latched comparator 650 and an SR flip-flop 660. The latched comparator 650 can include, for example, PMOS transistors 601, 602, 603, and 604, NMOS transistors 610, 611, 612, and 613, and input transistors 620, 621, 622, 630, 631, and 632. The SR flip-flop 660 can be constituted by NAND gates 640 and 641. In the configuration example shown in FIG. 6, when the clock signal of the four-input comparator 181 is in a low state, the latched comparator 650 is in a reset state, comparison result 1 and comparison result 2, which are the output signals, are in a high state, and the SR flip-flop 660 is in a holding state. When the clock signal is in a high state, the latched comparator 650 generates an internal signal corresponding to the differential voltage between each of the three input signals and the reference signal, and outputs the results according to these internal signals as the comparison results 1 and 2. The SR flip-flop 660 outputs a signal corresponding to the comparison results 1 and 2. In the four-input comparator 181, if the total voltage of input signal 1—reference voltage, input signal 2—reference voltage, and input signal 3—reference voltage is, for example, a positive voltage, the comparison result 1 will be low, the comparison result 2 will be high, and the output signal will be high.

The configuration example in FIG. 6 shows a four-input comparator, but it is possible to obtain a configuration corresponding to a third-order or higher continuous-time delta-sigma AD converter by increasing the number of input transistors.

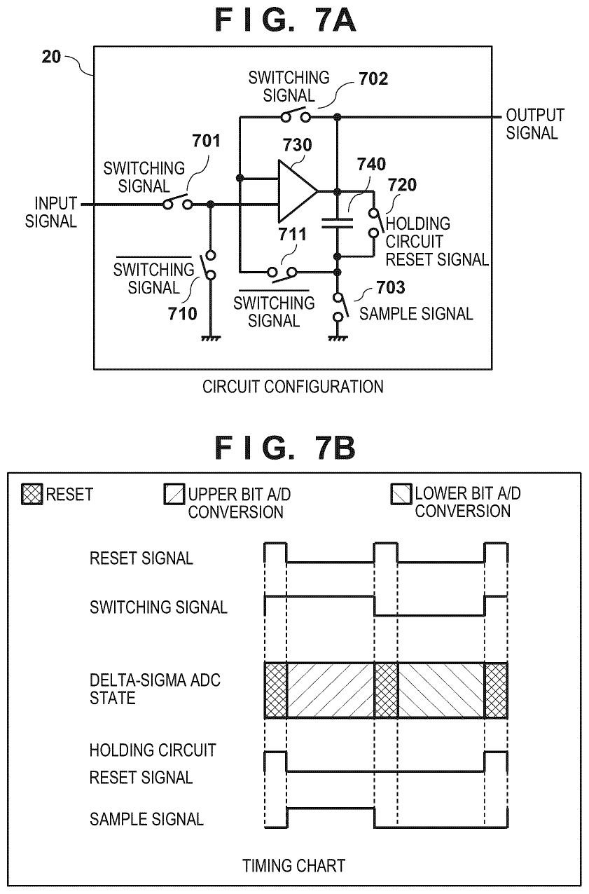

FIG. 7A shows a configuration example of the residual voltage holding circuit 20. FIG. 7B shows a timing chart relating to the operation of the residual voltage holding circuit 20. The residual voltage holding circuit 20 includes, for example, switches 701, 702, 703, 710, 711, and 720, an amplifier 730, and a sample capacitor 740. The switches 701 and 702 are controlled by switching signals. The switch 703 is controlled by a sample signal. The switches 710 and 711 are controlled by inverted switching signals. The switch 720 is controlled by a holding circuit reset signal. When the switching signals are in a high state, the holding circuit reset signal is in a high state, and the sample signal is in a low state, the sample capacitor 740 is reset. When the switching signals are in a high state, the holding circuit set signal is in a low state, and the sample signal is in a high state, a voltage signal corresponding to the input signal (the output of the continuous-time delta-sigma AD converter 10) is sampled by the sample capacitor 740. The voltage signal sampled at this time is the residual voltage after AD conversion, which corresponds to the upper bit string. When the switching signal is in a low state, the hold circuit reset signal is in a low state, and the sample signal is in a low state, the sampled voltage signal is held in the sample capacitor 740. In this configuration, the input signal sampling operation and the holding of the sampled input signal are realized by a single amplifier 730, which makes it possible to reduce power consumption and reduce the mounting area. Note that although an operation example has been shown here in which the switching signal is in a high state during the AD conversion period (first period) of the upper bit string, the operating period of the residual voltage holding circuit 20 can be reduced, and power consumption can be reduced by setting the switching signal to a high state at any time up to the end of the AD conversion of the upper bit string.

The digital demodulation circuit 40 shown in FIG. 1 outputs a multi-bit demodulated signal by performing digital signal processing according to Equation (2) on a 1-bit time-series delta-sigma modulated signal corresponding to the upper bit string of the continuous-time delta-sigma AD converter 10.

$$\begin{matrix}[ Math . 2 ] & \\ Upper bit demodulated signal = \frac{2}{M ( M + 1 )} {\sum }_{K = 1}^{M} {\sum }_{i = 1}^{K} DACin [ i ] & ( 2 )\end{matrix}$$

Here, M represents the oversampling ratio in AD conversion corresponding to the upper bit string in the continuous-time delta-sigma AD converter 10, and i represents the time index of the comparison results output in a time series. The digital demodulation circuit 40 performs digital signal processing according to Equation (3) on a 1-bit time-series delta-sigma modulated signal corresponding to the lower bit string in the continuous-time delta-sigma AD converter 10, and outputs a multi-bit demodulated signal.

$$\begin{matrix}[ Math . 3 ] & \\ Lower bit demodulated signal = \frac{2}{N ( N + 1 )} {\sum }_{K = 1}^{N} {\sum }_{i = 1}^{K} DACin [ i ] & ( 3 )\end{matrix}$$

Here, N represents the oversampling ratio in AD conversion corresponding to the lower bit string in the continuous-time delta-sigma AD converter 10, and i represents the time index of the comparison results output in a time series.

The reconstruction circuit 50 shown in FIG. 1 performs reconstruction processing on the upper bit demodulated signal and the lower bit demodulated signal according to Equation (4). In this reconstruction processing, if the signal obtained by combining the upper bit demodulated signal and the lower bit demodulated signal is assumed to be a decimal number (it is actually a binary signal), it is normalized such that the maximum value in the decimal number is 1. For example, if a signal with a value of 15 in decimal notation is generated, the reconstruction processing multiplies the upper bit demodulated signal and the lower bit demodulated signal by 1/15. In this way, a final digital signal is obtained, which is the final A/D conversion result of M+L bits normalized with the maximum value being 1 when converted to a decimal number.

$$\begin{matrix}[ Math . 4 ] & \\ Final digital signal = Upper bit demodulated signal + \frac{2}{M ( M + 1 )} Lower bit demodulated signal & ( 4 )\end{matrix}$$

It should be noted that M and N may be the same or different from each other.

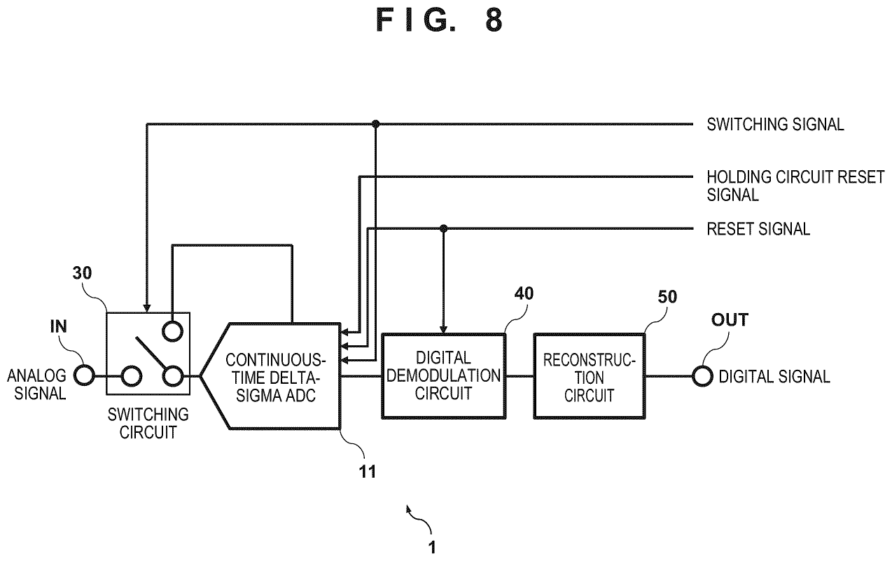

FIG. 8 shows a configuration of an AD conversion circuit 1 according to a second embodiment of the present disclosure. The AD conversion circuit 1 is configured as a two-stage continuous-time delta-sigma AD conversion circuit. The AD conversion circuit 1 converts an analog signal provided to an input terminal IN into a digital signal and outputs the result from an output terminal OUT. The AD conversion circuit 1 can include a continuous-time delta-sigma AD converter 11 and a switching circuit 30. The AD conversion circuit 1 can also include a digital demodulation circuit 40 and a reconstruction circuit 50. The continuous-time delta-sigma AD converter 11 can include an integration circuit that integrates the differential signal. During a first period, the switching circuit 30 provides the analog signal provided to the input terminal IN to the continuous-time delta-sigma AD converter 10. In addition, during a second period after the first period, the switching circuit 30 provides a voltage signal corresponding to the voltage output from the integration circuit of the continuous-time delta-sigma AD converter 11 at the end of the first period to the continuous-time delta-sigma AD converter 11. The first period is a period during which AD conversion is performed to generate a upper bit string of a digital signal corresponding to an analog signal provided to the input terminal IN. The second period is a period during which AD conversion is performed to generate a lower bit string of a digital signal corresponding to the analog signal provided to the input terminal IN. The upper bit string can be constituted by a plurality of bits. In addition, the lower bit string can be constituted by a plurality of bits.

The continuous-time delta-sigma AD converter 11 holds (samples) a voltage signal corresponding to the residual voltage output from the continuous-time delta-sigma AD converter 11 at the end of the first period, and supplies the voltage signal to the switching circuit 30 in the second period.

In the first period, the continuous-time delta-sigma AD converter 11 performs A/D conversion corresponding to the upper bit string. In addition, a voltage signal corresponding to the residual voltage held (sampled) by the continuous-time delta-sigma AD converter 11 at the end of the first period is provided to the input terminal of the continuous-time delta-sigma AD converter 11 via the switching circuit 30. Thereafter, in the second period, the continuous-time delta-sigma AD converter 11 performs A/D conversion corresponding to the lower bit string. In the first period, the time-series delta-sigma modulated signal (upper bit string) output from the continuous-time delta-sigma AD converter 11 is demodulated by the digital demodulation circuit 40 into respective multi-bit digital signals. In addition, in the second period, the time-series delta-sigma modulated signal (lower bit string) output from the continuous-time delta-sigma AD converter 10 is demodulated by the digital demodulation circuit 40 into respective multi-bit digital signals. The reconstruction circuit 50 generates an output digital signal based on the digital signals of the upper bit string and the digital signals of the lower bit string demodulated by the digital demodulation circuit 40. The internal signals of the continuous-time delta-sigma AD converter 11 and the digital demodulation circuit 40 are reset in accordance with the reset signal before the start of the first period and before the start of the second period. With this configuration, the continuous-time delta-sigma AD converter 11 holds a voltage signal corresponding to the residual voltage at the end of the first period, whereby it is possible to realize the AD conversion circuit 1 serving as a two-stage continuous-time delta-sigma AD conversion circuit.

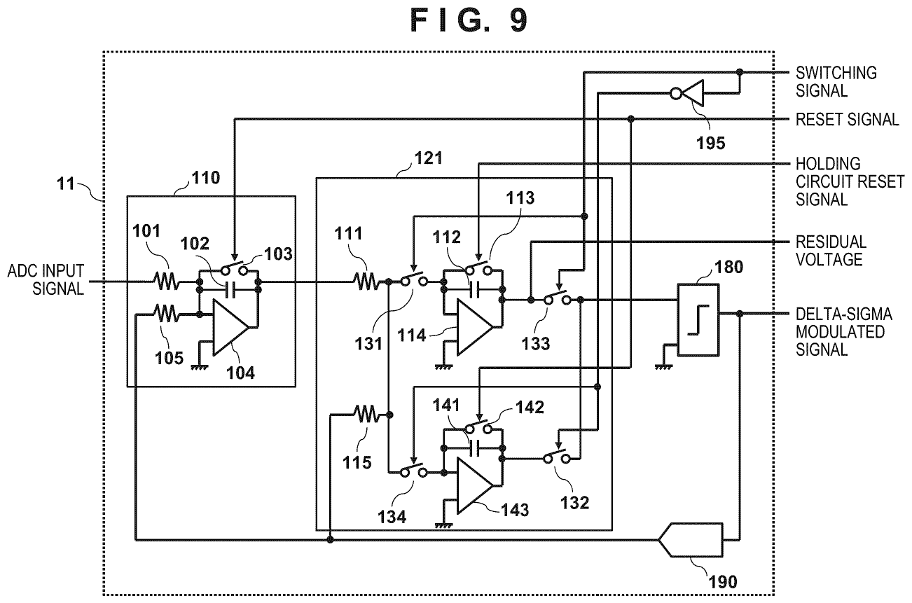

FIG. 9 shows a configuration of a second-order continuous-time delta-sigma AD converter as a first configuration example of the continuous-time delta-sigma AD converter 11. The continuous-time delta-sigma AD converter 11 of the first configuration example can include a first integrator 110, a second integrator 121, a comparator 180, a digital-to-analog converter (DA converter) 190, and an inverter 195. The first integrator 110 can include, for example, resistors 101 and 105, a capacitor 102, a switch 103, and an amplifier 104. The second integrator 121 can include, for example, resistors 111 and 115, capacitors 112 and 141, switches 113, 131, 132, 133, 134 and 142, and amplifiers 114 and 143.

The input terminal of the first integrator 110 is supplied with the output of the switching circuit 30 as an ADC input signal. The output of the first integrator 110 is provided to the second integrator 121, and the output of the second integrator 121 is provided to the comparator 180. The output of the comparator 180 is supplied to the DA converter 190, and the output of the DA converter 190 is supplied to the resistor 105 in the first integrator 110 and the resistor 115 in the second integrator 121. The output of the second integrator 121 is output as a residual voltage of the continuous-time delta-sigma AD converter 11.

When the switching signal is in a high state, an integrator constituted by the resistors 111 and 115, the switches 113, 131 and 133, the capacitor 112, and the amplifier 114 performs an integration operation in the A/D conversion corresponding to the above-described upper bit string. After the A/D conversion corresponding to the upper bit string ends, the switching signal enters a low state, and the capacitor 112 and the amplifier 114 hold a voltage signal corresponding to the residual voltage. When the switching signal is in the low state, the integrator constituted by the resistors 111 and 115, the switches 132, 134, and 142, the capacitor 141, and the amplifier 143 performs an integration operation in A/D conversion corresponding to the lower bit string. In this configuration, the residual voltage holding circuit is realized by the second integrator 121, whereby it is possible to reduce the number of control signals and the number of switches, thereby reducing the mounting area.

In the example of FIG. 9, the AD conversion circuit 1 is configured as a second-order continuous-time delta-sigma AD circuit. In the example of FIG. 9, the comparator 180 and the DA converter 190 of the AD conversion circuit 1 each have a 1-bit configuration. However, the comparator 180 and the DA converter 190 may be multi-bit, and the resistor 105 of the first integrator 110 and the resistor 115 of the second integrator 121 may be increased in number according to the resolution of the comparator 180 and the DA converter 190 and connected in parallel. In addition, a third-order or higher continuous-time delta-sigma AD converter may be configured by adding one or more integrators between the second integrator 121 and the comparator 180. By increasing the number of integrators, the AD conversion speed of the continuous-time delta-sigma AD converter 10 can be increased.

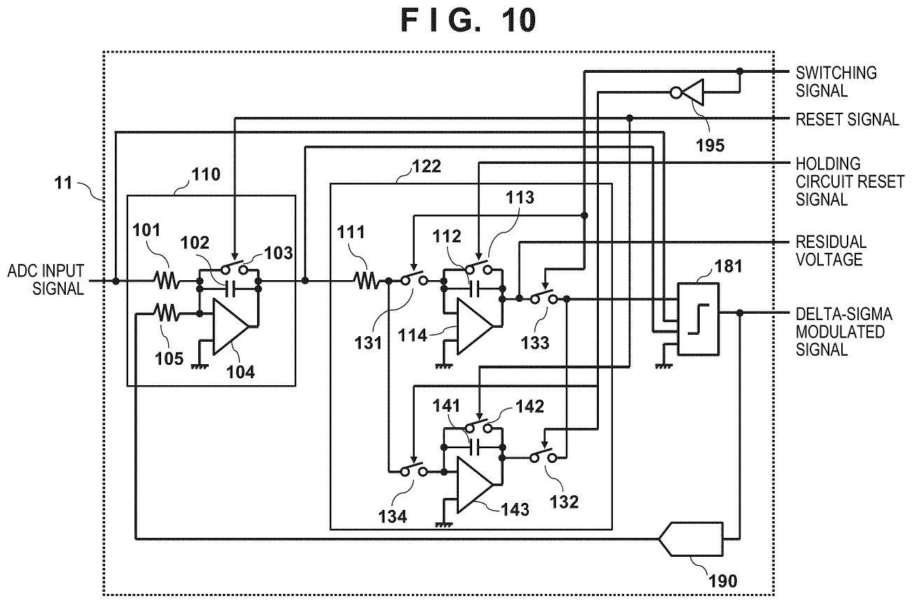

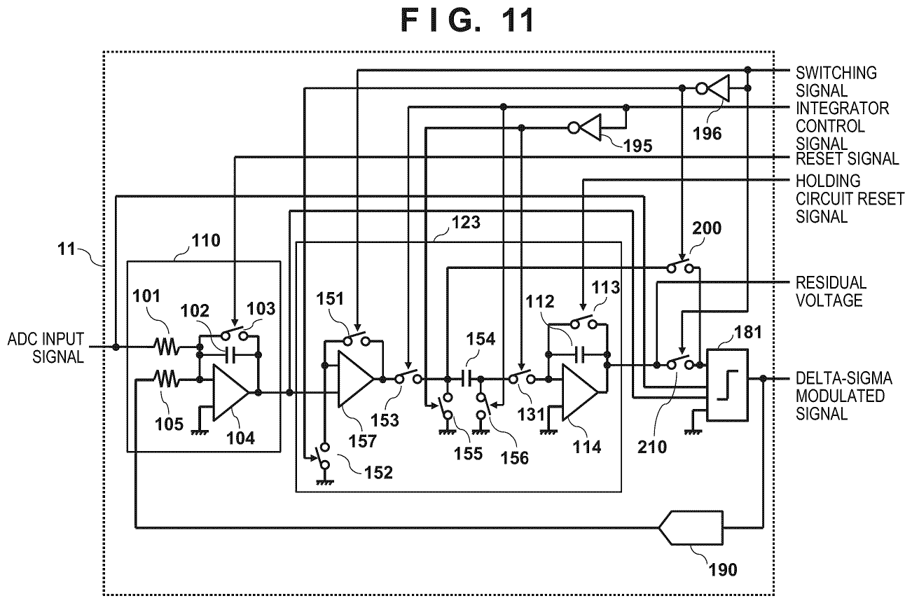

FIG. 10 shows a configuration of a second-order continuous-time delta-sigma AD converter having a feedforward path as a second configuration example of the continuous-time delta-sigma AD converter 11. The continuous-time delta-sigma AD converter 11 of the second configuration example can include a first integrator 110, a second integrator 122, a four-input comparator 181, a digital-to-analog converter (DA converter) 190, and an inverter 195. The first integrator 110 can include, for example, resistors 101 and 105, a capacitor 102, a switch 103, and an amplifier 104. The second integrator 122 can include, for example, a resistor 111, capacitors 112 and 141, switches 113, 131, 132, 133, 134 and 142, and amplifiers 114 and 143. The operation of the continuous-time delta-sigma AD converter 11 of the second configuration example shown in FIG. 10 is similar to the operation of the continuous-time delta-sigma AD converter 11 of the first configuration example shown in FIG. 9, and has the advantages described in the second configuration example of the first embodiment (FIG. 4).

In the example of FIG. 10, the AD conversion circuit 1 is configured as a second-order continuous-time delta-sigma AD circuit. In the example of FIG. 10, the four-input comparator 181 and the DA converter 190 of the AD conversion circuit 1 each have a one-bit configuration. However, the four-input comparator 181 and the DA converter 190 may be multi-bit, and the resistor 105 of the first integrator 110 may be increased in number according to the resolution of the four-input comparator 181 and the DA converter 190 and connected in parallel. In addition, a third-order or higher continuous-time delta-sigma AD converter may be configured by adding one or more integrators between the second integrator 122 and the four-input comparator 181.

FIG. 11 shows a configuration of a second-order continuous-time delta-sigma AD converter having a feedforward path as a third configuration example of the continuous-time delta-sigma AD converter 11. The continuous-time delta-sigma AD converter 11 of the third configuration example can include a first integrator 110, a second integrator 123, a four-input comparator 181, a DA converter 190, an inverter 195, switches 200 and 210, and inverters 195 and 196. The first integrator 110 can include, for example, resistors 101 and 105, a capacitor 102, a switch 103, and an amplifier 104. The second integrator 123 can include, for example, capacitors 112 and 154, switches 113, 131, 151, 152, 153, 155 and 156, and amplifiers 114 and 157.

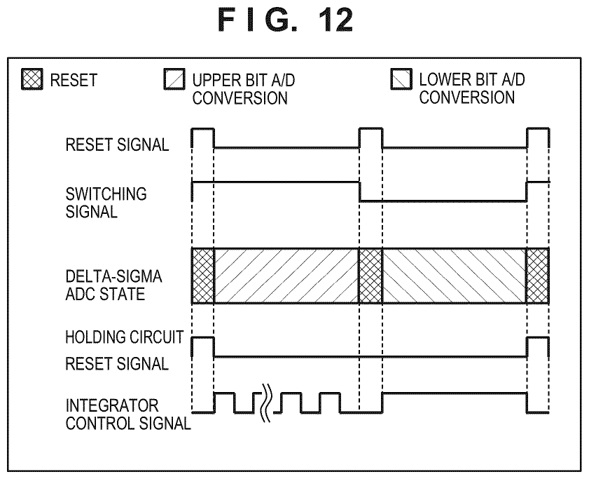

FIG. 12 shows the operation of the continuous-time delta-sigma AD converter 11 of the third configuration example in FIG. 11. In the continuous-time delta-sigma AD converter 11 of the third configuration example, the operation of the second integrator 123 differs between the A/D conversion corresponding to the upper bit string and the A/D conversion corresponding to the lower bit string. During A/D conversion corresponding to the upper bit string, an integration operation is performed by the switched capacitor integrator constituted by the capacitor 112, the switches 113, 131, 153, 155, and 156, and the amplifier 114. On the other hand, during A/D conversion corresponding to the lower bit string, an integration operation is performed by the gm-C integrator constituted by the switches 153, 156, 151, and 152 and the amplifier 157. During A/D conversion corresponding to the lower bit string, a voltage signal corresponding to the residual voltage signal is output by the holding circuit constituted by the capacitor 112 and the amplifier 114. The internal signal of the second integrator 123 supplied to the four-input comparator 181 differs between the A/D conversion corresponding to the upper bit string and the A/D conversion corresponding to the lower bit string, and is switched by the switches 200 and 210. By configuring second integrator 123 in this way, the number of resistors can be reduced and the mounting area can be reduced, compared to the configuration shown in FIG. 10.

In the example of FIG. 11, the AD conversion circuit 1 is configured as a second-order continuous-time delta-sigma AD circuit. In the example of FIG. 11, the four-input comparator 181 and the DA converter 190 of the AD conversion circuit 1 each have a one-bit configuration. However, the four-input comparator 181 and the DA converter 190 may be multi-bit, and the resistor 105 of the first integrator 110 may be increased in number according to the resolution of the four-input comparator 181 and the DA converter 190 and connected in parallel. In addition, a third-order or higher continuous-time delta-sigma AD converter may be configured by adding one or more integrators between the first integrator 110 and the second integrator 123.

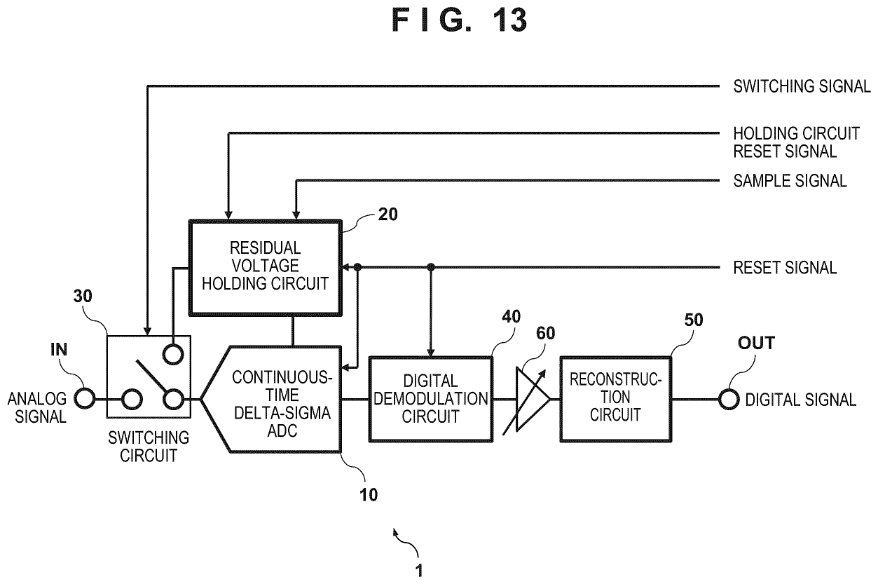

FIG. 13 shows a configuration of an AD conversion circuit 1 according to a third embodiment of the present disclosure. The AD conversion circuit 1 is configured as a two-stage continuous-time delta-sigma AD conversion circuit. The AD conversion circuit 1 converts an analog signal provided to an input terminal IN into a digital signal and outputs the digital signal from an output terminal OUT. The AD conversion circuit 1 can include a continuous-time delta-sigma AD converter 10 and a switching circuit 30. The AD conversion circuit 1 can also include a residual voltage holding circuit 20, a digital demodulation circuit 40, a reconstruction circuit 50, and a digital gain adjustment circuit 60. The continuous-time delta-sigma AD converter 10 can include an integration circuit that integrates a differential signal. During a first period, the switching circuit 30 provides the analog signal provided to the input terminal IN to the continuous-time delta-sigma AD converter 10. In addition, during a second period after the first period, the switching circuit 30 provides a voltage signal corresponding to the voltage output from the integration circuit of the continuous-time delta-sigma AD converter 10 at the end of the first period to the continuous-time delta-sigma AD converter 10. The first period is a period during which AD conversion is performed to generate an upper bit string of a digital signal corresponding to the analog signal provided to the input terminal IN. The second period is a period during which AD conversion is performed to generate a lower bit string of a digital signal corresponding to the analog signal provided to the input terminal IN. The upper bit string can be constituted by a plurality of bits. In addition, the lower bit string can be constituted by a plurality of bits.

The residual voltage holding circuit 20 holds (samples) a voltage signal corresponding to the residual voltage output from the continuous-time delta-sigma AD converter 10 at the end of the first period, and supplies the voltage signal to the switching circuit 30 in the second period. The residual voltage holding circuit 20 can be controlled by, for example, a holding circuit reset signal and a sample signal.

In the first period, the continuous-time delta-sigma AD converter 10 performs A/D conversion corresponding to the upper bit string, and at the end of the first period, a voltage signal corresponding to the residual voltage held by the residual voltage holding circuit 20 is provided to the continuous-time delta-sigma AD converter 10 by the switching circuit 30. Thereafter, in the second period, the continuous-time delta-sigma AD converter 10 performs A/D conversion corresponding to the lower bit string. In the first period, the time-series delta-sigma modulated signal (upper bit string) output from the continuous-time delta-sigma AD converter 10 is demodulated by the digital demodulation circuit 40 into respective multi-bit digital signals. In addition, in the second period, the time-series delta-sigma modulated signal (lower bit string) output from the continuous-time delta-sigma AD converter 10 is demodulated by the digital demodulation circuit 40 into respective multi-bit digital signals. The reconstruction circuit 50 generates an output digital signal based on the digital signals of the upper bit string and the digital signals of the lower bit string demodulated by the digital demodulation circuit 40. The internal signal of the continuous-time delta-sigma AD converter 10, the voltage signal held by the residual voltage holding circuit 20, and the internal signal of the digital demodulation circuit 40 are reset before the start of the first period and before the start of the second period in accordance with the reset signal.

The digital gain adjustment circuit 60 can be disposed between the digital demodulation circuit 40 and the reconstruction circuit 50. The digital gain adjustment circuit 60 can perform gain adjustment on the digital signal output from the digital demodulation circuit 40 and supply the gain-adjusted digital signal to the reconstruction circuit 50. The digital gain adjustment circuit 60 can be configured, for example, to perform gain adjustment on the digital signal of the lower bit string output from the digital demodulation circuit 40, but not to perform gain adjustment on the digital signal of the upper bit string output from the digital demodulation circuit 40. Note that the digital gain (correction value) applied by the digital gain adjustment circuit 60 can be acquired prior to AD conversion of the analog signal that is the target of AD conversion. For example, a reference value analog signal is input to the AD conversion circuit 2, and a correction value can be generated by comparing the digital signal that is normally obtained (expected value) with the digital signal that is actually output from the AD conversion circuit 2. Note that to further improve the accuracy of the correction, it is advisable to use a plurality of reference value analog signals with different values to obtain the correction value.

In the residual voltage holding circuit 20, an inherent circuit error may occur, such as a gain error caused by the finite gain of the amplifier circuit. Such a gain error can cause an error from the theoretical values shown in Equations (2) and (3), between the upper bit demodulated signal and the lower bit demodulated signal. This can cause nonlinear distortion of the A/D converter and degrade performance. With this configuration, nonlinear distortion can be improved by digitally correcting the gain error of the residual voltage holding circuit.

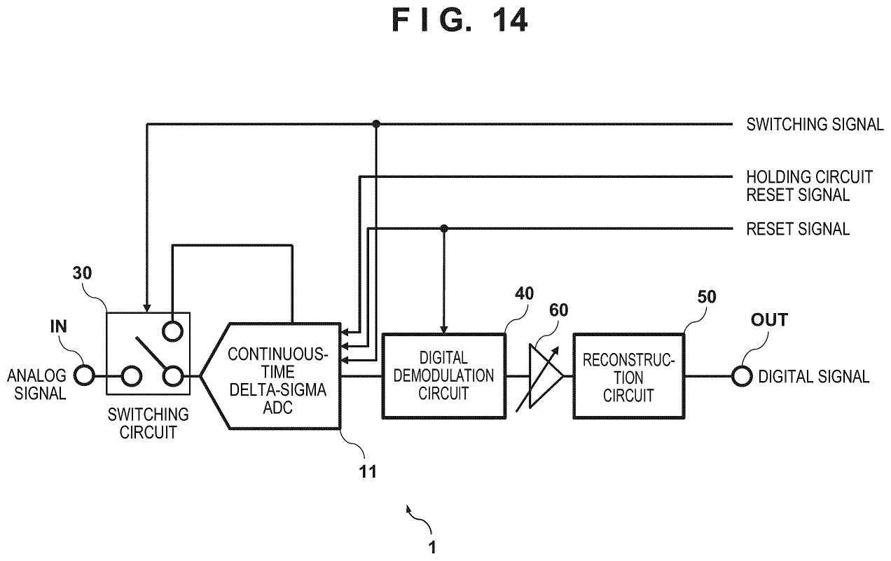

FIG. 14 shows another configuration example of the third embodiment of the present disclosure. The configuration example shown in FIG. 14 has a configuration in which a digital gain adjustment circuit 60 is added to the second embodiment (FIG. 8).

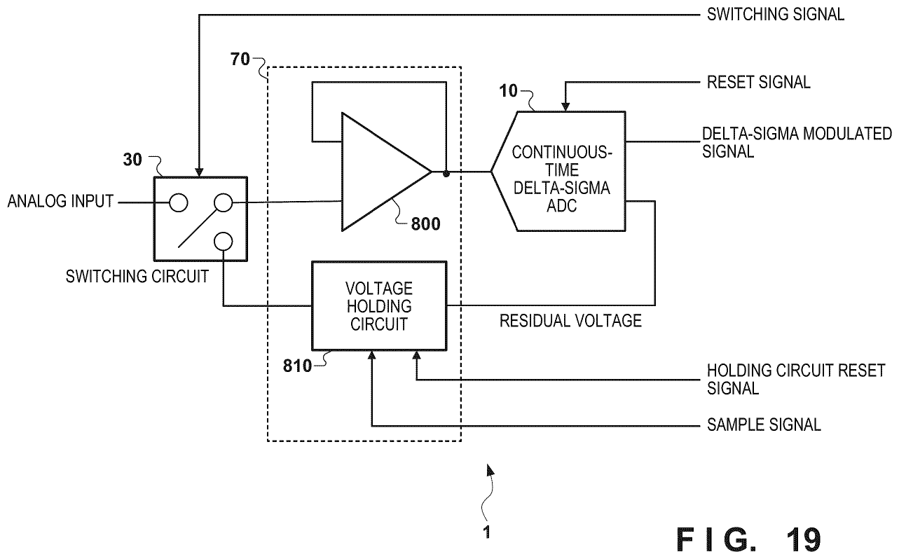

The configuration and operation of an analog circuit unit in a two-stage continuous-time delta-sigma AD conversion circuit 1 according to a fourth embodiment will be described with reference to FIGS. 18, 19, 20A, 20B, 21A, 21B, 21C, and 22. It should be noted that matters not mentioned in the fourth embodiment may be in accordance with the first to third embodiments. The AD conversion circuit 1 can include a continuous-time delta-sigma AD converter 10, a switching circuit 30, and a buffer circuit 70. Although not shown in the drawings, the continuous-time delta-sigma AD conversion circuit 1 can also include a digital demodulation circuit 40 and a reconstruction circuit 50, similar to the first to fourth embodiments.

In a first period, the switching circuit 30 provides the analog signal provided to the input terminal IN to the buffer circuit 70, and in a second period after the first period, the switching circuit 30 provides the residual voltage output from the continuous-time delta-sigma AD converter 10 at the end of the first period to the buffer circuit 70. The first period is a period during which AD conversion is performed to generate an upper bit string of the digital signal corresponding to the analog signal provided to the input terminal IN. The second period is a period during which AD conversion is performed to generate a lower bit string of the digital signal corresponding to the analog signal provided to the input terminal IN. The upper bit string can be constituted by a plurality of bits. In addition, the lower bit string can be constituted by a plurality of bits.

The buffer circuit 70 has a function of holding, over the second period, the residual voltage supplied from the continuous-time delta-sigma AD converter 10 via the switching circuit 30 at the end of the first period. The buffer circuit 70 is controlled by a hold circuit reset signal and a sample signal. During the first period in which A/D conversion is performed to generate the upper bit string, the buffer circuit 70 buffers the analog signal supplied to the input terminal IN of the switching circuit 30 and output from the switching circuit 30, and outputs the result to the continuous-time delta-sigma ADC 10. The buffer circuit 70 holds the residual voltage output from the continuous-time delta-sigma ADC 10 at the end of the first period for generating the upper bit string. Thereafter, in the second period, the buffer circuit 70 outputs, to the continuous-time delta-sigma ADC 10, a voltage obtained by buffering the held residual voltage, that is, a voltage corresponding to the residual voltage. That is, the buffer circuit 70 has a function of holding a voltage signal corresponding to the residual voltage output from the integration circuit of the continuous-time delta-sigma ADC 10 at the end of the first period.

The continuous-time delta-sigma ADC 1 can have a first integrator 110 at the input stage, as illustrated in FIG. 3. When the first integrator 110 has a voltage-current conversion circuit, a DC voltage corresponding to the input analog signal voltage flows through the voltage-current conversion circuit. For example, when a source follower circuit is used as a circuit that supplies an analog signal to the continuous-time delta-sigma ADC 10, a DC current value corresponding to the voltage value of the analog signal flows in addition to the bias current. This can cause a gain deviation in the source follower circuit, degrading the linearity of the analog signal. On the other hand, by disposing the buffer circuit 70 in the input path of the analog signal as in the fifth embodiment, the direct current that flows in the source follower circuit according to the voltage value of the analog signal is suppressed, thereby improving linearity. In addition, by sharing the circuit for holding the residual voltage and the amplifier of the buffer circuit 70, linearity can be improved without increasing the number of circuit components or power consumption.

FIG. 19 shows a first configuration example of the buffer circuit 70 having a function of holding a residual voltage. The buffer circuit 70 includes an amplifier 800 and a voltage holding circuit 810. The voltage holding circuit 810 is controlled by a holding circuit reset signal and a sample signal, and holds and outputs the residual voltage supplied from the continuous-time delta-sigma ADC 10. The buffer circuit 70 can be realized by configuring a voltage follower circuit using an amplifier 800 with two inputs and one output, for example.

In the first period, the analog signal provided to the input terminal IN is buffered using the amplifier 800. In the second period, the voltage held by the voltage holding circuit 810 (which has the function of holding the residual voltage) at the end of the first period is held and buffered using the amplifier 800 to generate a voltage signal.

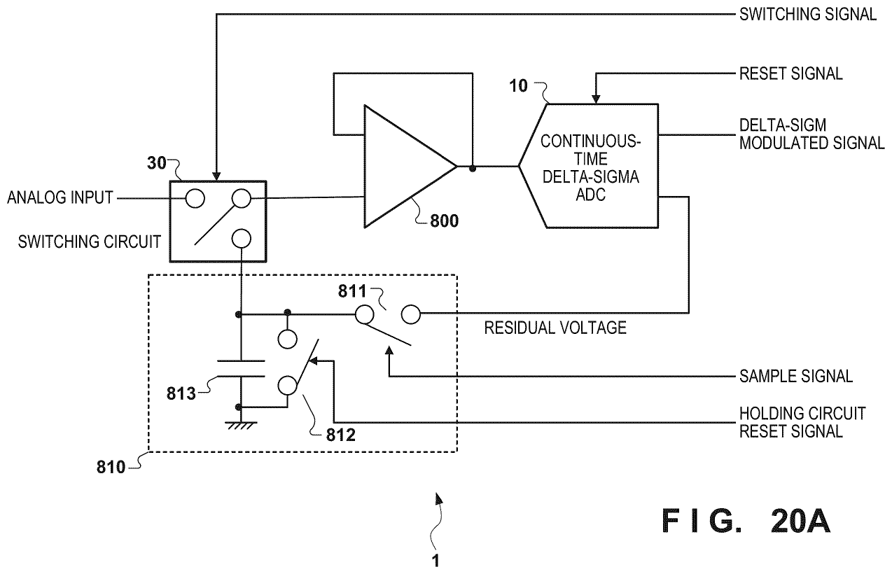

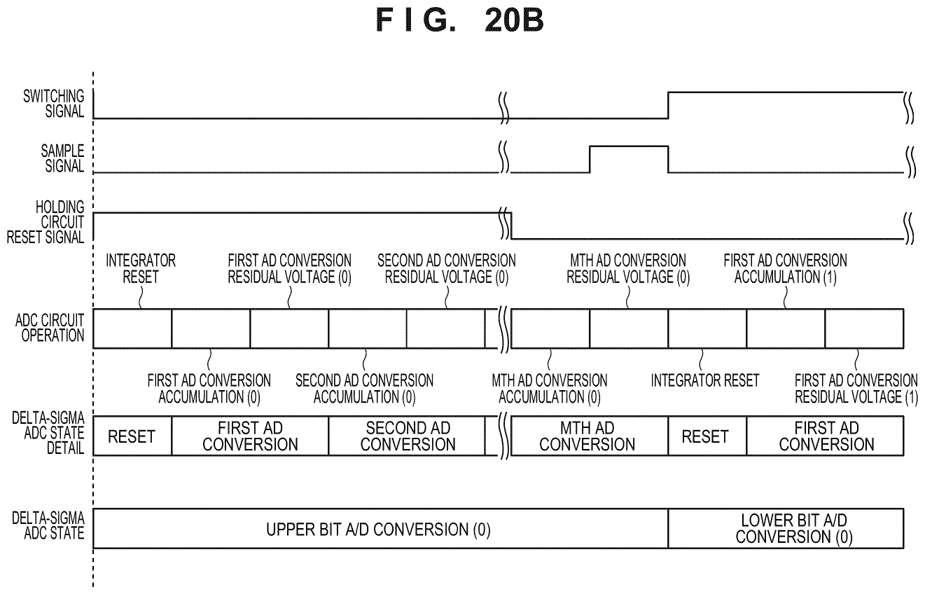

FIGS. 20A and 20B show a specific configuration example of a circuit including the switching circuit 30 and the buffer circuit 70, and a timing chart, respectively. The voltage holding circuit 810 is constituted by switches 811 and 812 and a capacitor 813. In the period during which the switching signal is low, the analog signal supplied to the input terminal IN is supplied to the buffer circuit 70 constituted by the amplifier 800 (voltage follower circuit), and the analog signal buffered by the voltage follower circuit is supplied to the continuous-time delta-sigma ADC 10. In the first period during which the continuous-time delta-sigma ADC 10 performs AD conversion to generate the upper bit string, the voltage follower circuit continues to buffer the analog signal until integrator accumulation of the A/D conversion of the final bit of the upper bit string is completed. Thereafter, the sample signal goes high, the residual voltage is stored in the capacitor 813, and after the sample signal goes low, the stored residual voltage is held until the holding circuit reset signal goes high. The switching circuit 30 supplies the output signal of the voltage holding circuit 810 to the continuous-time delta-sigma ADC 10 in the second period when AD conversion for generating the lower bit string is performed. Note that the holding circuit reset signal goes high at the start of the first period during which AD conversion is performed to generate the upper bit string, and can go low at any time before the final integrator accumulation operation in the first period.

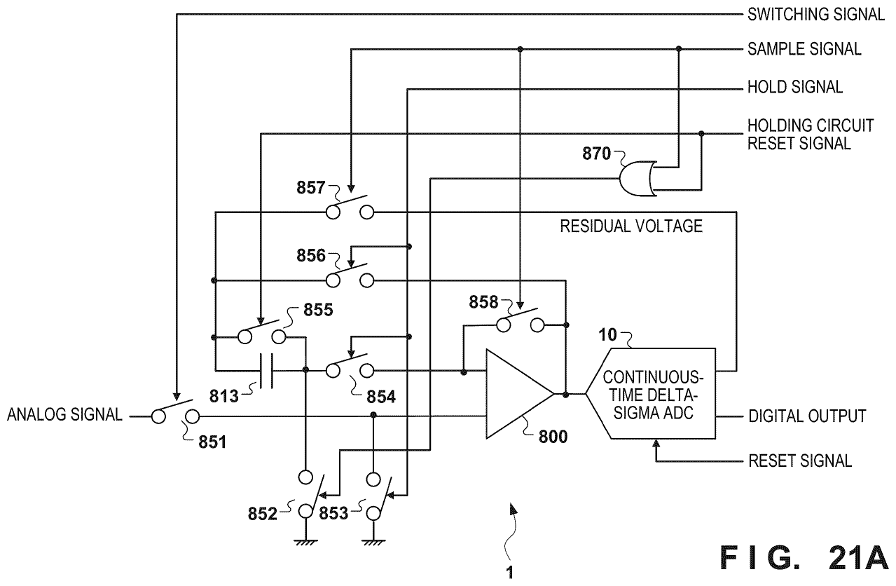

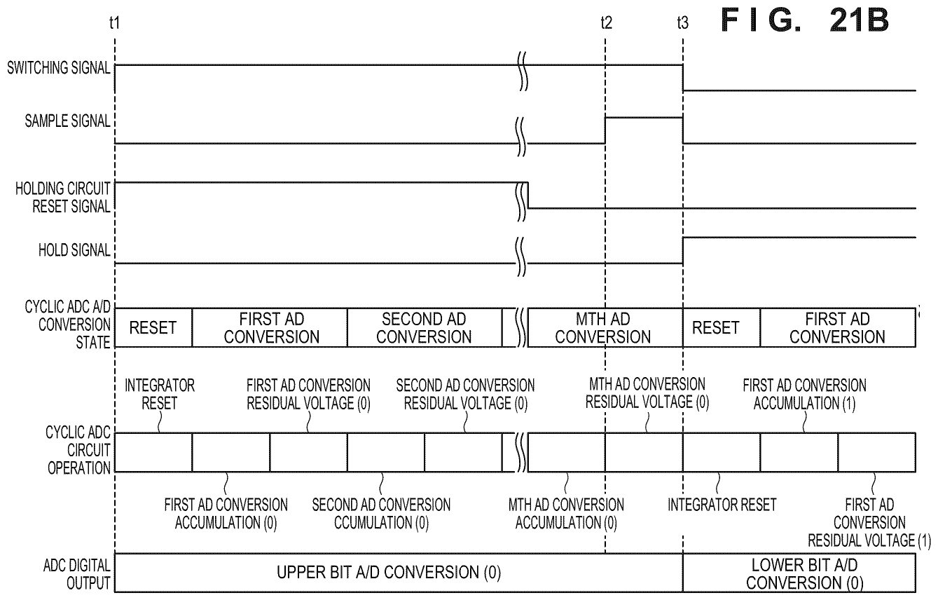

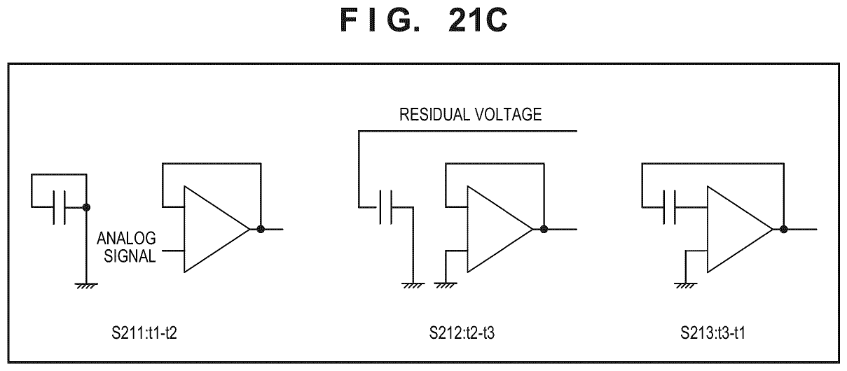

FIGS. 21A and 21B show a second configuration example of a circuit including the switching circuit 30 and the buffer circuit 70, and a timing chart, respectively. FIG. 21C shows a schematic diagram of the transition of the state of the buffer circuit. The switching circuit 30 and the buffer circuit 70 are constituted by switches 851, 852, 853, 854, 855, 856, 857, and 858, a capacitor 813, an OR circuit 870, and an amplifier 800. In the circuit of the second configuration example, at time t1, the switching signal goes high, the sample signal goes low, the holding circuit reset signal goes high, and the hold signal goes low, resulting in a state S211 in FIG. 21C. At this time, the analog signal is buffered by a voltage follower circuit constituted by the amplifier 800 and the switch 858, and the electric charge stored in the capacitor 813 is reset using the switches 852 and 855. Thereafter, at any time during the period from time t1 to time t2, the holding circuit reset signal goes low, completing the reset operation. At time t2, the sample signal goes high, causing the switches 857, 852 and the capacitor 813 to transition to a state S212 in FIG. 21C. In this state, the residual signal is sampled. At time t3, the switching signal goes low, the sample signal goes low, and the hold signal goes high, and the amplifier 800, the capacitor 813, and the switches 854, 856, and 853 enter a state S213 in FIG. 21C. In this state, the circuit forms a feedback circuit, and holds and buffers the signal sampled at time t2.

In this configuration, a feedback circuit using an amplifier holding and buffering the sampled signal is advantageous in that the ability to remove interference signals that get mixed into the capacitance via parasitic capacitance or the like is improved, and unnecessary errors in the residual voltage output during the holding period are reduced.

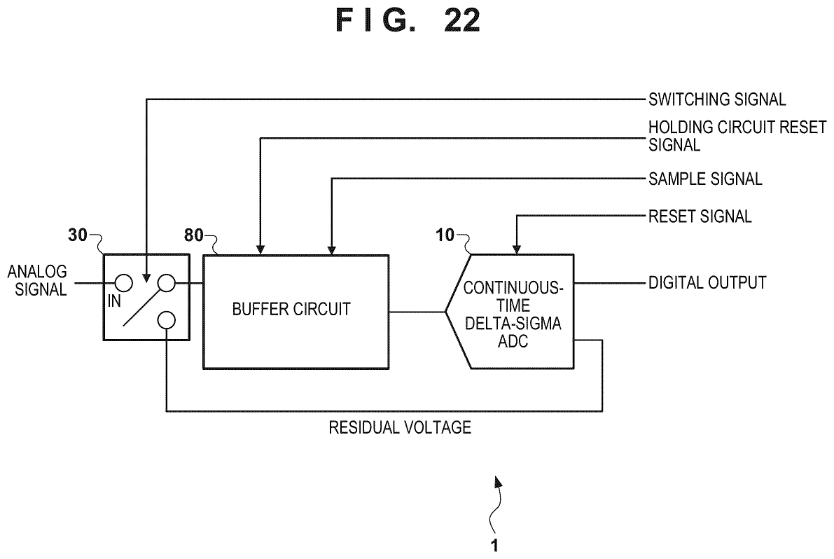

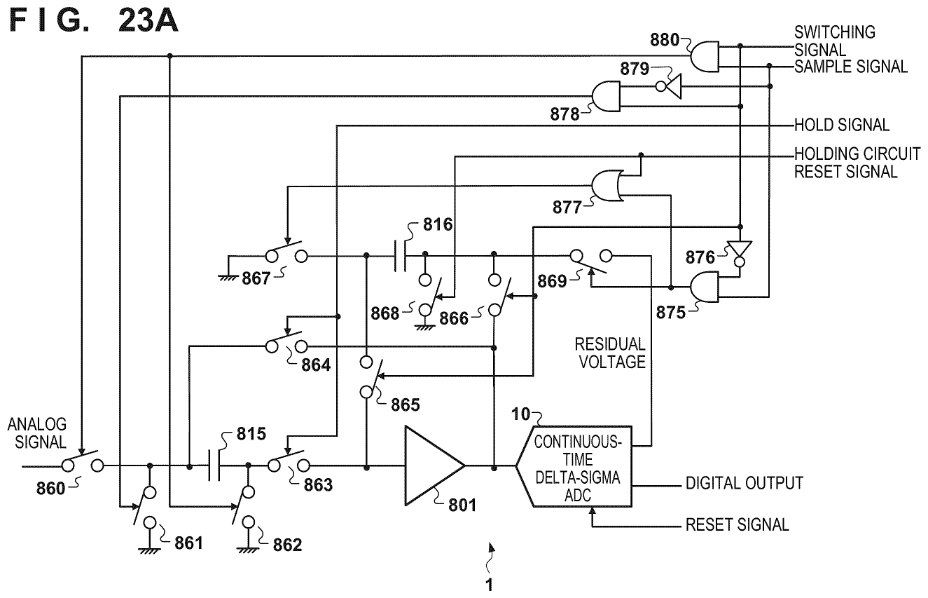

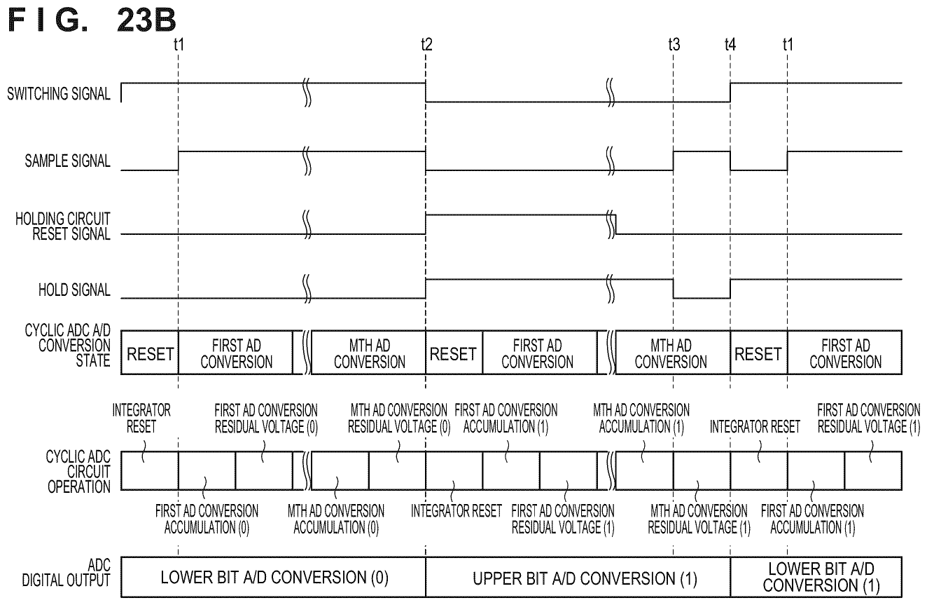

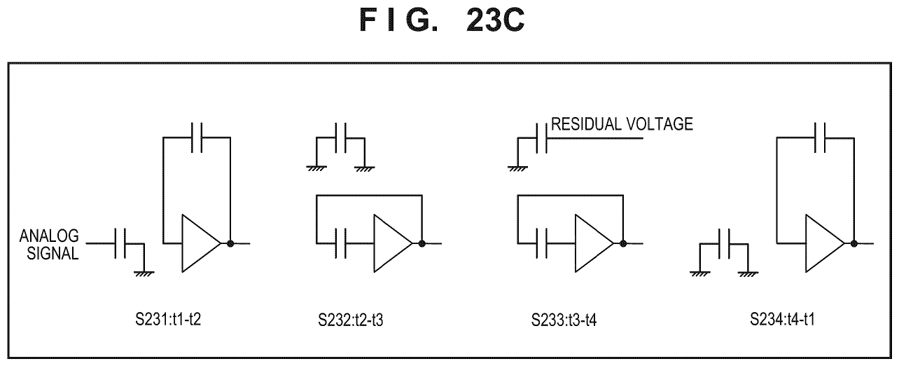

The configuration and operation of an analog circuit unit in a two-stage continuous-time delta-sigma AD conversion circuit 1 of a fifth embodiment will be described with reference to FIGS. 22, 23A, 23B, and 23C. Note that matters not mentioned in the fifth embodiment may be in accordance with the first to fourth embodiments. The AD conversion circuit 1 may include a continuous-time delta-sigma AD converter 10, a switching circuit 30, and a buffer circuit 80. Although not shown in the drawings, the continuous-time delta-sigma AD conversion circuit 1 can also include a digital demodulation circuit 40 and a reconstruction circuit 50, similarly to the first to fourth embodiments.

During a first period, the switching circuit 30 provides the analog signal provided to the input terminal IN to the buffer circuit 70, and during a second period after the first period, the switching circuit 30 provides the residual voltage output from the continuous-time delta-sigma AD converter 10 at the end of the first period to the buffer circuit 70. The first period is a period during which AD conversion is performed to generate an upper bit string of the digital signal corresponding to an analog signal provided to the input terminal IN. The second period is a period during which AD conversion is performed to generate a lower bit string of the digital signal corresponding to the analog signal provided to the input terminal IN. The upper bit string can be constituted by a plurality of bits. In addition, the lower bit string can be constituted by a plurality of bits.

The buffer circuit 80 has the function of holding the analog signal and the residual voltage. The buffer circuit 80 is controlled by a hold circuit reset signal and a sample signal. The buffer circuit 80 holds (samples and holds) the analog signal that is supplied to the input terminal IN of the switching circuit 30 and output from the switching circuit 30 at the start of the first period during which A/D conversion is performed to generate the upper bit string, buffers the held analog signal, and outputs the result over the first period. That is, the buffer circuit 80 has the function of holding the analog signal provided to the input terminal IN at the start of the first period. The buffer circuit 70 holds (samples and holds) the residual voltage output from the continuous-time delta-sigma ADC 10 at the end of the first period for generating the upper bit string. Thereafter, in a second period, the buffer circuit 70 outputs, to the continuous-time delta-sigma ADC 10, a voltage obtained by buffering the held residual voltage, that is, a voltage corresponding to the residual voltage. That is, the buffer circuit 80 has a function of holding a voltage signal corresponding to the residual voltage output from the integration circuit of the continuous-time delta-sigma ADC 10 at the end of the first period.

As described above, in the fifth embodiment, the function of a buffer circuit is added to the holding circuit that holds the residual voltage, and the function of sampling and holding an analog signal is also added. This allows the sampling of the analog signal and the holding period for providing the analog signal to the continuous-time delta-sigma AD conversion circuit to be pipelined operations. When the settling time of an analog signal provided to a continuous-time delta-sigma AD conversion circuit is long compared to the A/D conversion period, the pipeline operation of the circuit enables high-speed A/D conversion.

FIGS. 23A and 23B show a specific configuration example of a circuit including the switching circuit 30 and the buffer circuit 80, and a timing chart, respectively. The circuit is constituted by switches 860, 861, 862, 863, 864, 865, 866, 867, 868, and 869, capacitors 815 and 816, AND circuits 875, 878, and 880, an OR circuit 877, inverter circuits 876 and 879, and an amplifier 801. At time t1, the switching signal goes high, the sample signal goes high, the holding circuit reset signal goes low, and the hold signal goes low, and thus the circuit enters a state S231 in FIG. 23C. In this state, the analog signal is sampled by the capacitor 815 using the switches 860 and 862 while the sampled residual voltage is buffered by the feedback circuit constituted by the amplifier 801, the capacitor 816, and the switches 865 and 866. Thereafter, at time t2, the switching signal goes low, the sample signal goes low, the holding circuit reset signal goes high, and the hold signal goes high, resulting in a state S232 in FIG. 23C. At this time, the sampled analog signal is buffered by a feedback circuit constituted by the amplifier 801, the capacitor 815, and the switches 863 and 864, while the switches 867 and 868 are used to reset the capacitor 816. At any time during the period from time t2 to t3, the holding circuit reset signal goes low, and the reset operation of the capacitor 816 is completed. At time t3, the sample signal goes high, the hold signal goes low, and the residual voltage is sampled by a circuit constituted by the capacitor 816 and the switches 867 and 869. At time t4, the switching signal goes high, the sample signal goes low, and the hold signal goes high, resulting in a state S234 in FIG. 23C. The capacitor 815 is reset using the switches 861 and 862 while the sampled residual voltage is buffered in the feedback circuit constituted by the amplifier 801, the capacitor 816, and the switches 865 and 866. In the first period, the analog signal provided to the input terminal IN is held and buffered using the amplifier 801. In the second period, the voltage held by the holding circuit at the end of the first period is held and buffered using the amplifier 801 to generate a voltage signal.

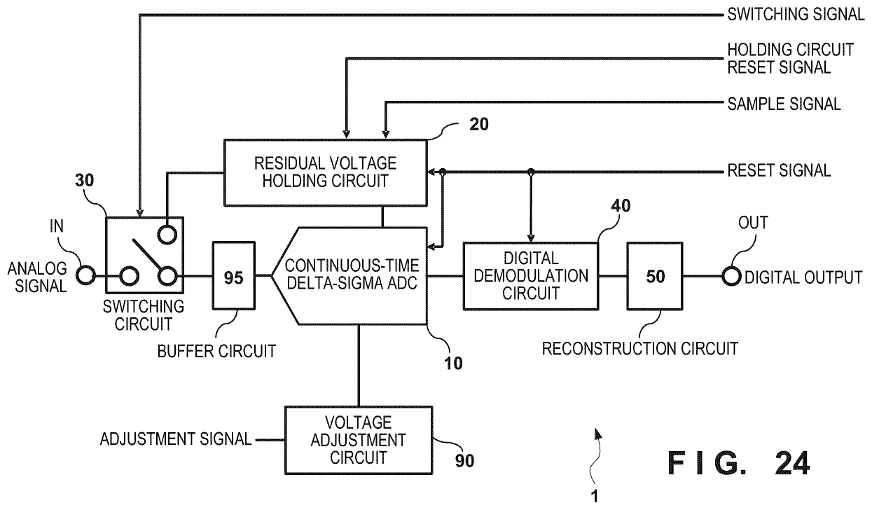

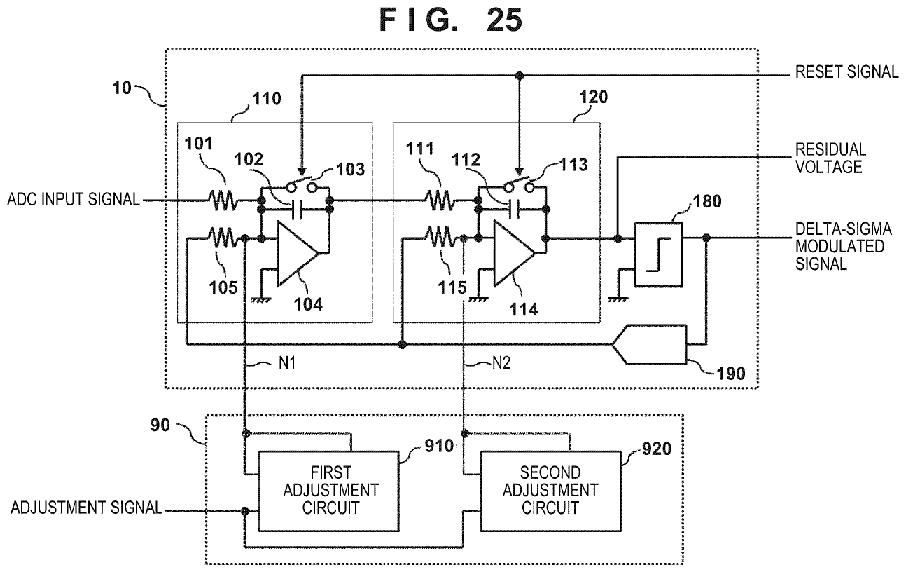

The configuration and operation of an analog circuit unit in a two-stage continuous-time delta-sigma AD conversion circuit 1 according to a sixth embodiment will be described with reference to FIGS. 24, 25, 26, and 27. Note that matters not mentioned in the sixth embodiment may be in accordance with the first to fifth embodiments. FIG. 24 shows the configuration of the AD conversion circuit 1 according to the sixth embodiment. The AD conversion circuit 1 can include a continuous-time delta-sigma ADC 10, a residual voltage holding circuit 20, a switching circuit 30, a digital demodulation circuit 40, a reconstruction circuit 50, a voltage adjustment circuit 90, and a buffer circuit 95. The continuous-time delta-sigma AD converter 10 can include an integration circuit that integrates a differential signal. During the first period, the switching circuit 30 provides the analog signal provided to the input terminal IN to the continuous-time delta-sigma AD converter 10 via the buffer circuit 95. In addition, during the second period after the first period, the switching circuit 30 provides a voltage signal corresponding to the voltage output from the integration circuit of the continuous-time delta-sigma AD converter 10 at the end of the first period to the continuous-time delta-sigma AD converter 10 via the buffer circuit 95.

The internal voltage of the continuous-time delta-sigma ADC 10 during the AD conversion period is adjusted by the voltage adjustment circuit 90 based on the adjustment signal to within a range close to the signal value of the adjustment signal. Adding the voltage adjustment circuit 90 that adjusts the internal voltage to the continuous-time delta-sigma ADC 10 provides the following advantage in addition to the advantages described in the fourth embodiment shown in FIG. 18. The advantage is that even if the operating point of the buffer circuit 95 differs from the operating point of the internal voltage in the continuous-time delta-sigma ADC 10, linearity is improved by adjusting the operating point of the internal voltage in the analog circuit in the continuous-time delta-sigma ADC 10 to within a range close to the signal value of the adjustment signal.

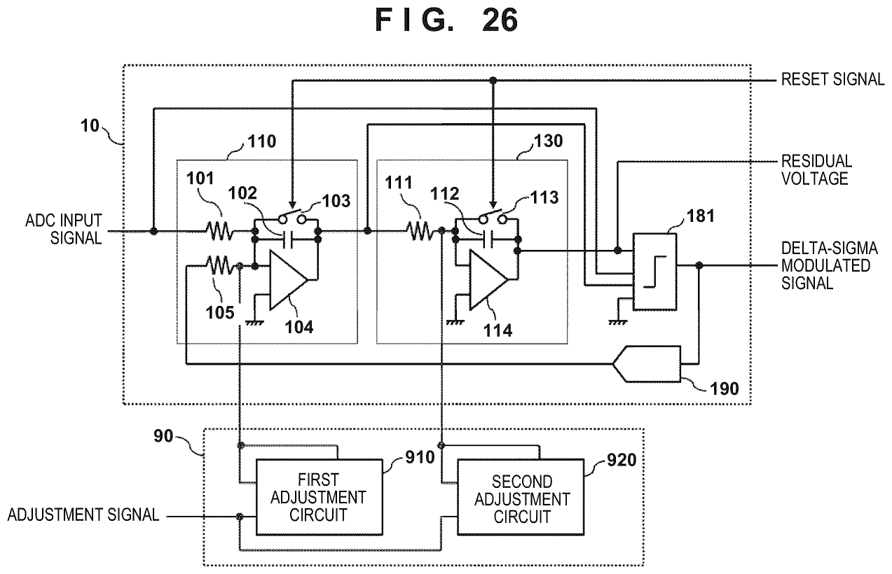

FIG. 25 shows a first configuration example of the continuous-time delta-sigma AD converter 10 and the voltage adjustment circuit 90 according to the sixth embodiment. The continuous-time delta-sigma ADC 10 can include a first integrator 110, a second integrator 120, a comparator 180, and a DA converter 190. The first integrator 110 can include, for example, resistors 101 and 105, a capacitor 102, a switch 103, and an amplifier 104. The second integrator 120 can include, for example, resistors 111 and 115, a capacitor 112, a switch 113, and an amplifier 114. The voltage adjustment circuit 90 can include a first adjustment circuit 910 and a second adjustment circuit 920. The operation of the continuous-time delta-sigma ADC 10 shown in FIG. 25 is similar to the operation of the continuous-time delta-sigma ADC 10 shown in FIG. 3.

The output of the first integrator 110 is supplied to the second integrator 120, and the output of the second integrator 120 is provided to the comparator 180. The output of the comparator 180 is supplied to the DA converter 190, and the output of the DA converter 190 is supplied to the resistor 105 in the first integrator 110 and the resistor 115 in the second integrator 120. The output of the second integrator 120 is output as a residual voltage of the continuous-time delta-sigma ADC 10.

In the first integrator 110, a first internal signal at a first internal node N1 to which the resistors 101 and 105, the capacitor 102, the switch 103 and the amplifier 104 are connected is connected to an adjustment node of the first adjustment circuit 910. The first internal signal at the first internal node N1 is adjusted by the first adjustment circuit 910 to within a range close to the signal value of the adjustment signal input to the first adjustment circuit 910 (i.e., within a predetermined range). In the second integrator 120, a second internal signal at a second internal node N2 to which the resistors 111 and 115, the capacitor 112, the switch 113, and the amplifier 114 are connected is adjusted by the second adjustment circuit 920 to within a range close to the adjustment signal input to the second adjustment circuit 920 (i.e., within a predetermined range). With the above-described configuration, during the AD conversion period of the continuous-time delta-sigma ADC 10, the first internal signal and the second internal signal in the first integrator 110 and the second integrator 120 are adjusted to within a range close to the adjusted signal.

Note that although FIG. 25 shows a configuration example of a single-phase circuit, the voltage of an internal node can be adjusted with a similar configuration even when the first integrator 110 and the second integrator 120 are differential circuits. In the case of a differential circuit, the voltage input as the adjustment signal is a common-mode signal, and the voltages of the first and second internal nodes adjusted by the first and second adjustment circuits are common-mode voltages.

In the example of FIG. 25, the AD conversion circuit 1 is configured as a second-order continuous-time delta-sigma ADC. In the example of FIG. 25, the comparator 180 and the DA converter 190 of the AD conversion circuit 1 each have a 1-bit configuration. However, the comparator 180 and the DA converter 190 may be multi-bit, and the resistor 105 of the first integrator 110 and the resistor 115 of the second integrator 120 may be increased in number according to the resolution of the comparator 180 and the DA converter 190 and connected in parallel. The AD conversion speed of the continuous-time delta-sigma AD converter 10 can be increased by configuring the comparator 180 and the DA converter 190 with a plurality of bits. In addition, a third-order or higher continuous-time delta-sigma AD converter may be configured by adding one or more integrators between the second integrator 120 and the comparator 180. The AD conversion speed of the continuous-time delta-sigma AD converter 10 can be increased by increasing the number of integrators.

FIG. 26 shows a second configuration example of the continuous-time delta-sigma AD converter 11 of the sixth embodiment. The continuous-time delta-sigma ADC 10 may include a first integrator 110, a second integrator 130, a four-input comparator 181, and a DA converter 190. The first integrator 110 can include, for example, resistors 101 and 105, a capacitor 102, a switch 103, and an amplifier 104. The second integrator 130 can include, for example, a resistor 111, a capacitor 112, a switch 113, and an amplifier 114. A voltage adjustment circuit 90 can include a first adjustment circuit 910 and a second adjustment circuit 920.

The output of the first integrator 110 is supplied to the second integrator 120, and the output of the second integrator 120 is supplied to the four-input comparator 181. The output of the four-input comparator 181 is supplied to the DA converter 190, and the output of the DA converter 190 is supplied to the resistor 105 in the first integrator 110. The output of the second integrator 130 is output as a residual voltage of the continuous-time delta-sigma ADC 10.

In the first integrator 110, a first internal signal at a first internal node to which the resistors 101 and 105, the capacitor 102, the switch 103, and the amplifier 104 are connected is connected to an adjustment node of the first adjustment circuit 910. The first internal signal at the internal node is adjusted by the first adjustment circuit 910 to within a range close to the signal value of the adjusted signal input to the first adjustment circuit 910. In the second integrator 130, a second internal signal at a second internal node to which the resistor 111, the capacitor 112, the switch 113, and the amplifier 114 are connected is adjusted by the second adjustment circuit 920 to within a range close to the adjustment signal input to the second adjustment circuit 920. With the above configuration, during the AD conversion period of the continuous-time delta-sigma ADC 10, the first internal signal and the second internal signal of the first integrator 110 and the second integrator 130 are adjusted to within a range close to the adjustment signal.

Note that although FIG. 26 shows a configuration example of a single-phase circuit, the internal voltage can be adjusted with a similar configuration even when the first integrator 110 and the second integrator 120 are differential circuits. In the case of a differential circuit, the voltage input as the adjustment signal is a common-mode signal, and the first and second internal voltages adjusted by the first and second adjustment circuits are common-mode voltages.

The operation of the continuous-time delta-sigma ADC 10 shown in FIG. 26 is similar to the operation of the continuous-time delta-sigma ADC 10 shown in FIG. 3. In the continuous-time delta-sigma ADC 10 shown in FIG. 26, a signal supplied as an ADC input signal from the switching circuit 30 is supplied to the four-input comparator 181. The output of the first integrator 110 and the output of the second integrator 130 are supplied to the four-input comparator 181. With this configuration, it is possible to suppress the amplitude of the signals output from the first integrator 110 and the second integrator 130, and the influence of the nonlinearity of the amplifiers 104 and 114 can be suppressed. This makes it possible to improve the nonlinear distortion characteristics of the continuous-time delta-sigma AD converter 10.

In the example of FIG. 26, the AD conversion circuit 1 is configured as a second-order continuous-time delta-sigma ADC. In the example of FIG. 26, the four-input comparator 181 and the DA converter 190 of the AD conversion circuit 1 each have a one-bit configuration. However, the four-input comparator 180 and the DA converter 190 may be multi-bit, and the resistor 105 of the first integrator 110 may be increased in number according to the resolution of the four-input comparator 181 and the DA converter 190 and connected in parallel. In addition, a third-order or higher continuous-time delta-sigma AD converter may be configured by adding one or more integrators between the second integrator 130 and the four-input comparator 181. The AD conversion speed of the continuous-time delta-sigma AD converter 10 can be increased by increasing the number of integrators.

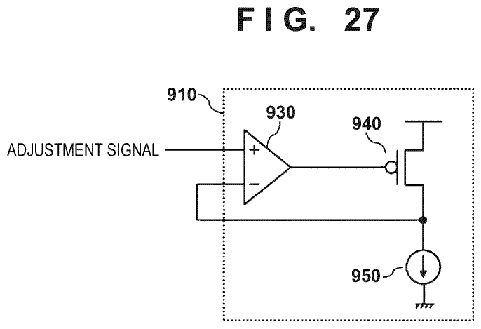

FIG. 27 shows a detailed configuration example of the first adjustment circuit 910. The first adjustment circuit 910 can be constituted by an amplifier 930, a PMOS transistor 940, and a current source 950. The adjustment signal is supplied to a non-inverting input terminal of the amplifier 930, and an internal node of the first integrator 110 can be connected to an inverting input terminal of the amplifier 930. The amplifier 930 can be connected to the gate of the PMOS transistor 940. The source of the PMOS transistor 940 can be connected to the current source 950 and the inverting input terminal of the amplifier 930. According to this configuration, the voltage of the internal node of the first integrator 110 is controlled to within a range close to the signal value of the adjustment signal through the principle of negative feedback. The second adjustment circuit 920 can have a similar configuration to the first adjustment circuit 910. The configuration shown in FIG. 25 is an example of a circuit that adjusts the voltage of the internal node to be adjusted through the principle of negative feedback, and other configurations that achieve the same function can be adopted to adjust the voltages of the internal nodes of the first integrator 110 and the second integrator 130.

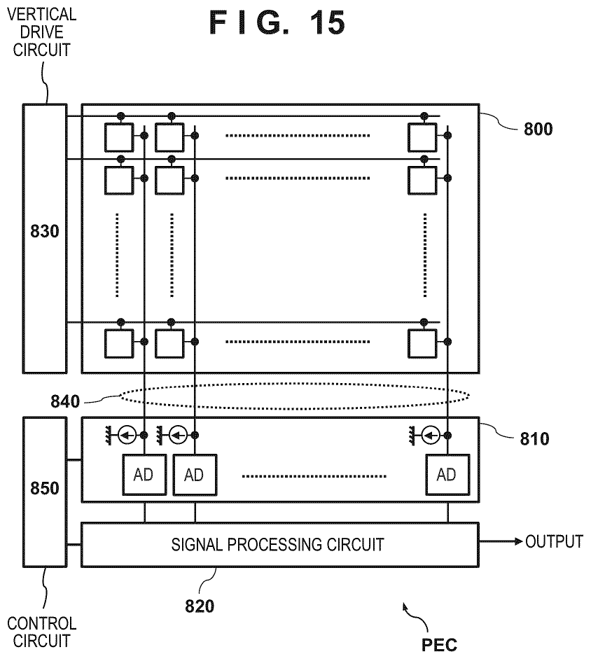

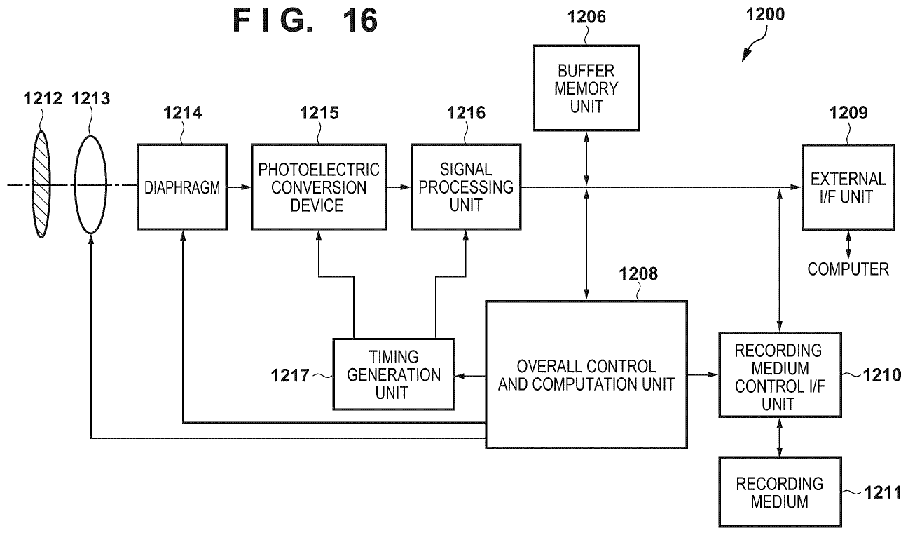

FIG. 15 shows a configuration of a photoelectric conversion device PEC according to a seventh embodiment of the present disclosure. The photoelectric conversion device PEC can be configured as a solid-state image capture device that captures and outputs an image. Alternatively, the photoelectric conversion device PEC can be configured as a device that captures an image and outputs a signal obtained from the captured image.

The photoelectric conversion device PEC can include, for example, a pixel array (array constituted by a plurality of photoelectric conversion units) 800, a vertical drive circuit 830, a readout circuit (current source, ADC) 810, a control circuit 850, and a signal processing circuit 820. The readout circuit 810 can include a plurality of current sources respectively connected to a plurality of vertical lines 840, and AD converters that perform AD conversion on signals output from pixels of a selected row to the plurality of vertical lines 840. Each AD converter in the readout circuit 810 can be a two-stage continuous-time delta-sigma AD conversion circuit typified by the first to fourth embodiments. This allows the readout circuit 810 to be made smaller.

The photoelectric conversion device PEC can be configured to read out the reset level from each pixel of the pixel array 800 and the optical signal level generated through photoelectric conversion using a readout circuit 810. The readout circuit 810 can be configured to output a digital signal of the reset level and a digital signal of the optical signal level. The signal processing circuit 820 can be configured to perform CDS processing on the digital signal of the reset level and the digital signal of the optical signal level, and output the signals resulting from CDS processing. The pixel array 800, the vertical drive circuit 830, the readout circuit 810, the control circuit 850, and the signal processing circuit 820 may be configured on a single substrate, may be distributed across a plurality of substrates and then stacked, or may be divided into a plurality of chips. The photoelectric conversion device PEC can be a CMOS image sensor. In addition, the photoelectric conversion device PEC may be a front-illuminated sensor or a back-illuminated sensor.

An example of a photoelectric conversion system using the photoelectric conversion device PEC according to the seventh embodiment will be described below.

FIG. 16 is a block diagram showing a configuration of a photoelectric conversion system 1200 according to an embodiment. The photoelectric conversion system 1200 according to this embodiment includes a photoelectric conversion device 1215. Here, the photoelectric conversion device 1215 can be the photoelectric conversion device PEC according to the fourth embodiment. The photoelectric conversion system 1200 can be used, for example, as an image capture system. Specific examples of image capture systems include digital still cameras, digital camcorders, and surveillance cameras. FIG. 16 shows an example of a digital still camera as the photoelectric conversion system 1200.

The photoelectric conversion system 1200 shown in FIG. 16 has the photoelectric conversion device 1215, a lens 1213 that forms an optical image of a subject on the photoelectric conversion device 1215, a diaphragm 1214 for varying the amount of light that passes through the lens 1213, and a barrier 1212 for protecting the lens 1213. The lens 1213 and the diaphragm 1214 are an optical system that focuses light onto the photoelectric conversion device 1215. A photoelectric conversion system used for an image capture application is also called an image capture system.

The photoelectric conversion system 1200 includes a signal processing unit 1216 that processes an output signal output from the photoelectric conversion device 1215. The signal processing unit 1216 performs signal processing operations such as performing various corrections and compression on the input signal as necessary and outputting the result. The photoelectric conversion system 1200 further includes a buffer memory unit 1206 for temporarily storing image data, and an external interface unit (external I/F unit) 1209 for communicating with an external computer or the like. Furthermore, the photoelectric conversion system 1200 has a recording medium 1211 such as a semiconductor memory for recording or reading out image capture data, and a recording medium control interface unit (recording medium control I/F unit) 1210 for recording or reading out data to or from the recording medium 1211. The recording medium 1211 may be built into the photoelectric conversion system 1200 or may be detachable. In addition, communication from the recording medium control I/F unit 1210 to the recording medium 1211 and communication from the external I/F unit 1209 may be performed wirelessly.

The photoelectric conversion system 1200 further includes an overall control and computation unit 1208 that performs various types of computation and overall control of the digital still camera, and a timing generation unit 1217 that outputs various timing signals to the photoelectric conversion device 1215 and the signal processing unit 1216. Here, timing signals and the like may be input from outside, and the photoelectric conversion system 1200 need only have at least the photoelectric conversion device 1215 and the signal processing unit 1216 that processes the output signal output from the photoelectric conversion device 1215. The timing generation unit 1217 may be mounted in the photoelectric conversion device. The overall control and computation unit 1208 and the timing generation unit 1217 may be configured to perform some or all of the control functions of the photoelectric conversion device 1215.

The photoelectric conversion device 1215 outputs an image signal to the signal processing unit 1216. The signal processing unit 1216 performs predetermined signal processing on the image signal output from the photoelectric conversion device 1215 and outputs image data. In addition, the signal processing unit 1216 generates an image using the image signal. In addition, the signal processing unit 1216 may perform distance computation on the signal output from the photoelectric conversion device 1215. Note that the signal processing unit 1216 and the timing generation unit 1217 may be mounted on the photoelectric conversion device. That is, the signal processing unit 1216 and the timing generation unit 1217 may be provided on the substrate on which the pixels are arranged, or may be provided on a different substrate. By configuring an image capture system using the photoelectric conversion device according to each of the above-described embodiments, it is possible to realize an image capture system capable of acquiring higher-quality images.

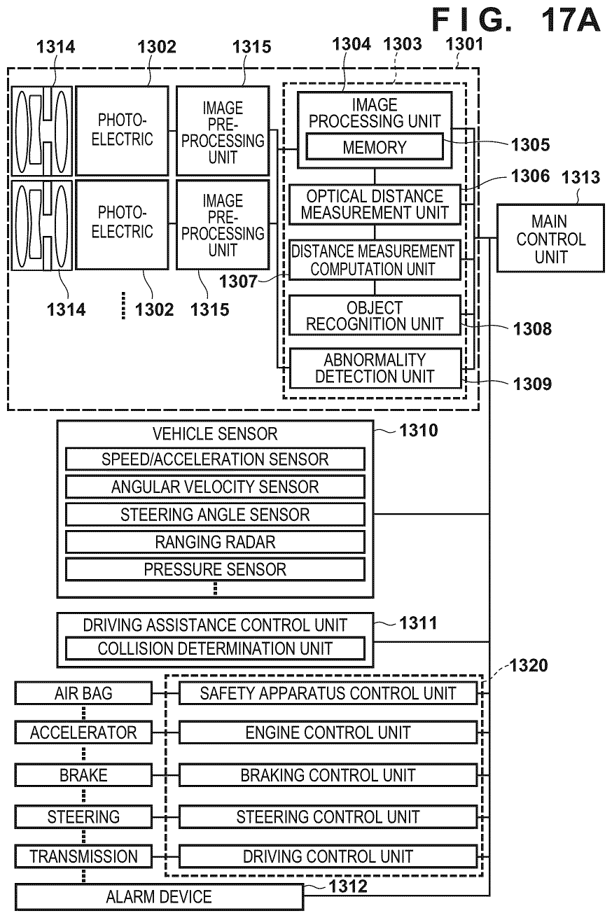

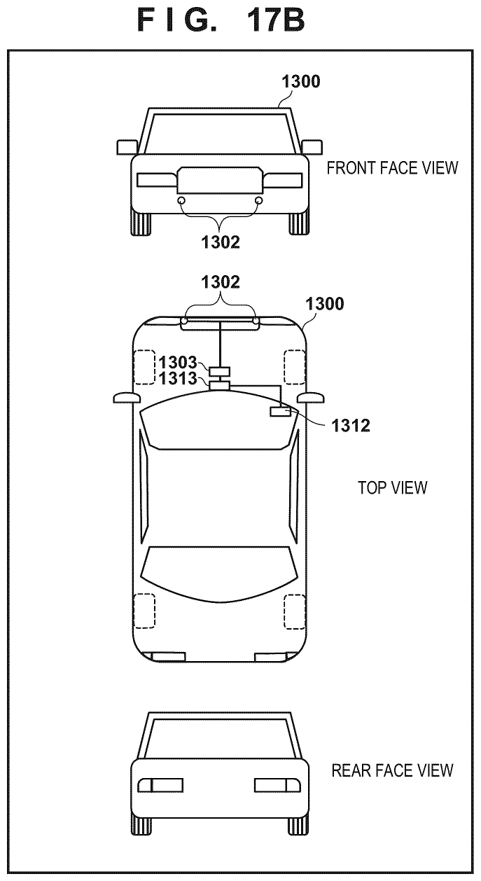

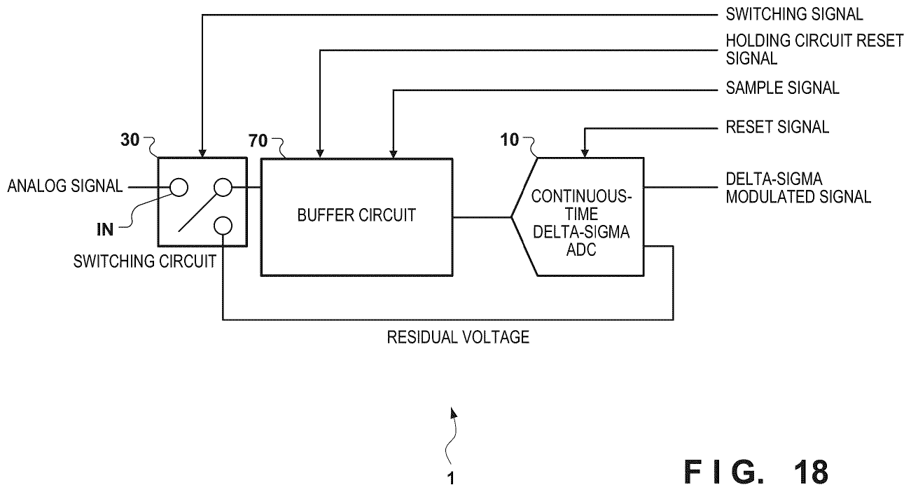

A photoelectric conversion system or a mobile object according to another embodiment will be described with reference to FIGS. 17A and 17B. FIGS. 17A and 17B are schematic diagrams showing a configuration example of the photoelectric conversion system or mobile object according to this embodiment, and this embodiment shows an example of an in-vehicle camera as a photoelectric conversion system.

FIGS. 17A and 17B show an example of a vehicle system and a photoelectric conversion system mounted therein for capturing images. A photoelectric conversion system 1301 includes a photoelectric conversion device 1302, an image pre-processing unit 1315, an integrated circuit 1303, and an optical system 1314. The optical system 1314 forms an optical image of a subject on the photoelectric conversion device 1302. The photoelectric conversion device 1302 converts the optical image of the subject formed by the optical system 1314 into an electrical signal. The photoelectric conversion device 1302 is a photoelectric conversion device according to any one of the above-described embodiments. The image pre-processing unit 1315 performs predetermined signal processing on the signal output from the photoelectric conversion device 1302. The functions of the image pre-processing unit 1315 may be incorporated into the photoelectric conversion device 1302. The photoelectric conversion system 1301 is provided with at least two sets of the optical system 1314, the photoelectric conversion device 1302, and the image pre-processing unit 1315, and the output from the image pre-processing unit 1315 of each set is input to the integrated circuit 1303.

The integrated circuit 1303 is an integrated circuit for use in an image capture system, and includes an image processing unit 1304 including a memory 1305, an optical distance measurement unit 1306, a distance measurement computation unit 1307, an object recognition unit 1308, and an abnormality detection unit 1309. The image processing unit 1304 performs image processing such as development processing and defect correction on the output signal of the image pre-processing unit 1315. The memory 1305 temporarily stores the captured image and stores the defect positions of the captured pixels. The optical distance measurement unit 1306 performs focusing and distance measurement of the subject. The distance measurement computation unit 1307 computes distance measurement information from a plurality of pieces of image data acquired by a plurality of photoelectric conversion devices 1302. The object recognition unit 1308 recognizes subjects such as cars, roads, signs, and people. When the abnormality detection unit 1309 detects an abnormality in the photoelectric conversion device 1302, it notifies a main control unit 1313 of the abnormality.

The integrated circuit 1303 may be realized by specially designed hardware, by a software module, or by a combination of these. The integrated circuit 1303 may also be realized by a field-programmable gate array (FPGA), an application-specific integrated circuit (ASIC), or a combination thereof.

The main control unit 1313 performs overall control of the operations of the photoelectric conversion system 1301, a vehicle sensor 1310, a control unit 1320, and the like. It is also possible to use a method in which the main control unit 1313 is not provided, and the photoelectric conversion system 1301, the vehicle sensor 1310, and the control unit 1320 each have their own communication interface and send and receive control signals via a communication network (e.g., CAN standard).

The integrated circuit 1303 has a function of receiving a control signal from the main control unit 1313 or transmitting a control signal or a setting value to the photoelectric conversion device 1302 by its own control unit.

The photoelectric conversion system 1301 is connected to the vehicle sensor 1310 and can detect the vehicle's travel state, such as vehicle speed, yaw rate, and steering angle, as well as the state of the environment outside the vehicle and other vehicles and obstacles. The vehicle sensor 1310 is also a distance information acquisition means for acquiring information on the distance to an object. The photoelectric conversion system 1301 is also connected to a driving assistance control unit 1311 that performs various driving assistance functions such as automatic steering, automatic cruising, and a collision prevention function. In particular, the collision determination function estimates and determines whether or not a collision has occurred with another vehicle or obstacle based on the detection results of the photoelectric conversion system 1301 and the vehicle sensor 1310. As a result, avoidance control when a collision is predicted, and safety device activation in the event of a collision are performed.

The photoelectric conversion system 1301 is also connected to an alarm device 1312 that issues an alarm to the driver based on the result of the collision determination unit. For example, if the collision determination unit determines that there is a high likelihood of a collision, the main control unit 1313 performs vehicle control to avoid a collision and mitigate damage by applying the brakes, releasing the accelerator, or suppressing engine output. The alarm device 1312 warns the user by sounding an alarm, displaying alarm information on a display screen of a car navigation system or meter panel, or vibrating a seat belt or steering wheel.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. An AD conversion circuit for converting an analog signal provided to an input terminal into a digital signal, comprising:
a continuous-time delta-sigma AD converter including an integration circuit configured to integrate a differential signal; and
a switching circuit configured to, during a first period, provide the analog signal provided to the input terminal to the continuous-time delta-sigma AD converter, and during a second period after the first period, provide a voltage signal that corresponds to the voltage output from the integration circuit at the end of the first period to the continuous-time delta-sigma AD converter.

2. The AD conversion circuit according to claim 1, further comprising
a holding circuit configured to hold the voltage signal corresponding to the voltage output from the integration circuit at the end of the first period and provide the voltage signal to the continuous-time delta-sigma AD converter via the switching circuit during the second period.

3. The AD conversion circuit according to claim 2, wherein
the holding circuit includes an amplifier circuit configured to amplify the voltage output from the integration circuit, and a capacitor configured to hold an output of the amplifier circuit as the voltage signal.

4. The AD conversion circuit according to claim 1, wherein
the continuous-time delta-sigma AD converter includes a first integrator and a second integrator connected to an output of the first integrator, and
the integration circuit is the second integrator.

5. The AD conversion circuit according to claim 1, wherein
the integration circuit is a gm-C integrator.

6. The AD conversion circuit according to claim 1, wherein
the continuous-time delta-sigma AD converter further includes:
a comparator configured to compare the output of the integration circuit with a reference signal; and
a DA converter configured to convert the output of the comparator into an analog signal and supply the analog signal to the integration circuit.

7. The AD conversion circuit according to claim 6, wherein
the continuous-time delta-sigma AD converter includes a first integrator and a second integrator connected to an output of the first integrator, and
the integration circuit is the second integrator.

8. The AD conversion circuit according to claim 7, wherein
the comparator compares the analog signal, the output of the first integrator, and the output of the second integrator with the reference signal.

9. The AD conversion circuit according to claim 1, wherein
the integration circuit holds the voltage signal corresponding to the voltage output from the integration circuit at the end of the first period.

10. The AD conversion circuit according to claim 9, wherein
the continuous-time delta-sigma AD converter includes a first integrator and a second integrator connected to an output of the first integrator,
the integration circuit is the second integrator, and
the second integrator includes a holding circuit configured to hold the voltage signal corresponding to the voltage output from the first integrator at the end of the first period.

11. The AD conversion circuit according to claim 1, further comprising:
a digital demodulation circuit configured to generate a digital signal of an upper bit string based on an output of the continuous-time delta-sigma AD converter in the first period, and generate a digital signal of a lower bit string based on an output of the continuous-time delta-sigma AD converter in the second period; and
a reconstruction circuit configured to generate an output digital signal based on the digital signal of the upper bit string and the digital signal of the lower bit string.

12. The AD conversion circuit according to claim 11, further comprising
a gain adjustment circuit disposed between the digital demodulation circuit and the reconstruction circuit,
wherein the gain adjustment circuit performs gain adjustment on the digital signal of the lower bit string.

13. The AD conversion circuit according to claim 1, wherein
the continuous-time delta-sigma AD converter is reset between the first period and the second period.

14. The AD conversion circuit according to claim 1, further comprising
a buffer circuit configured to buffer the output of the switching circuit and supply the buffered output to the continuous-time delta-sigma AD converter.

15. The AD conversion circuit according to claim 14, wherein
the buffer circuit has a function of holding the voltage output from the integration circuit at the end of the first period,
the buffer circuit includes an amplifier,
in the first period, the analog signal provided to the input terminal is buffered using the amplifier, and
in the second period, the voltage held by the function at the end of the first period is held and buffered using the amplifier to generate the voltage signal.

16. The AD conversion circuit according to claim 14, wherein
the buffer circuit has a function of holding the voltage output from the integration circuit at the end of the first period, and the buffer circuit generates the voltage signal in the second period by buffering the voltage held by the function at the end of the first period, and
the buffer circuit has a function of holding the analog signal provided to the input terminal at the start of the first period, and in the first period, the buffer circuit buffers and outputs the analog signal held by the function at the start of the first period.

17. An AD conversion circuit for converting an analog signal provided to an input terminal into a digital signal, comprising:
a continuous-time delta-sigma AD converter including an integration circuit configured to integrate a differential signal; and
a circuit configured to, during a first period, provide the analog signal provided to the input terminal to the continuous-time delta-sigma AD converter, and during a second period after the first period, provide a voltage signal that corresponds to the voltage output from the integration circuit at the end of the first period to the continuous-time delta-sigma AD converter.

18. A photoelectric conversion device comprising:
a photoelectric conversion unit; and
the AD conversion circuit according to claim 1, configured to convert an analog signal output by the photoelectric conversion unit into a digital signal.

19. An image capture device comprising:
the photoelectric conversion device according to claim 18; and
a signal processing unit configured to process a signal output from the photoelectric conversion device.

20. A mobile object comprising the image capture device according to claim 19.
